(19) United States
(12) Patent Application Publication
(10) Pub. No.: US 2014/0159235 A1
(43) Pub. Date: Jun. 12, 2014

(54) ELECTRONIC COMPONENT, ELECTRONIC APPARATUS INCLUDING THE SAME, AND MANUFACTURING METHOD OF THE ELECTRONIC APPARATUS

(71) Applicant: FUJITSU LIMITED, Kawasaki-shi (JP)

(72) Inventor: Muneyuki Odaira, Isehara (JP)

(73) Assignee: FUJITSU LIMITED, Kawasaki-shi (JP)

(21) Appl. No.: 14/073,144

(22) Filed: Nov. 6, 2013

(30) Foreign Application Priority Data
Dec. 6, 2012 (JP) 2012-267528

(51) Int. Cl. H01L 23/00

(52) U.S. Cl. CPC H01L 24/13; H01L 24/11
USPC 257/737; 438/614

(57) ABSTRACT

An electronic component includes an electrode portion and a solder portion formed on the electrode portion. In the electronic component, the electrode portion includes a first conductive portion and a second conductive portion each having different diffusion coefficient with respect to a component of the solder portion on a top surface of the electrode portion, and the solder portion is formed on the first conductive portion and the second conductive portion.

### CROSS-REFERENCE TO RELATED APPLICATION

This application is based upon and claims the benefit of priority from the prior Japanese Patent Application No. 2012-267528 filed on Dec. 6, 2012, the entire contents of which are incorporated herein by reference.

### FIELD

The present disclosure relates to an electronic component, an electronic apparatus including the electronic component, and a manufacturing method of the electronic apparatus.

### BACKGROUND

An electronic component such as a semiconductor element which uses an electrode referred to as a pillar (also referred to as a post) has been known. A technique has been known in which an electrode of the electronic component is bonded to an electrode (e.g., a pillar) of a counterpart electronic component such as a semiconductor element using solder formed on the electrode to electrically connect both electrodes. A diffusion and reaction of an electrode component and a solder component may occur during a bonding process. A technique of forming a barrier layer, on an electrode, having a property that a diffusion and reaction of the solder component is hard to occur compared to the electrode also has been known.

Further, conventionally, a technique of forming a barrier metal between a solder bump and an underlying pad has been known from a point of view that suppresses diffusion and reaction of the solder component. See, for example, Japanese Patent Application Laid-Open No. 2010-263208 and Japanese Patent Application Laid-Open No. 2003-31576.

### SUMMARY

According to an aspect of the present invention, an electronic component includes an electrode portion and a solder portion formed on the electrode portion. In the electronic component, the electrode portion includes a first conductive portion and a second conductive portion having different diffusion coefficients with respect to a component of the solder portion and formed on a top surface of the electrode portion, and the solder portion is formed on the first conductive portion and the second conductive portion.

The object and advantages of the invention will be realized and attained by means of the elements and combinations particularly pointed out in the claims. It is to be understood that both the foregoing general description and the following detailed description are exemplary and explanatory, and are not restrictive of the invention, as claimed.

### BRIEF DESCRIPTION OF DRAWINGS

FIGS. 1A and 1B are views illustrating an exemplary semiconductor device.

FIG. 2 is a view illustrating an exemplary terminal.

FIGS. 3A and 3B are explanatory views of an example of bonding between terminals.

FIGS. 4A and 4B are views illustrating an exemplary terminal according to a first embodiment.

FIGS. 5A to 5D are explanatory views of an example of bonding between terminals according to the first embodiment.

FIGS. 6A and 6B are explanatory views of another example of bonding between terminals according to the first embodiment.

FIGS. 7A to 7C are explanatory (first) views of an example of a terminal forming method according to the first embodiment.

FIGS. 8A to 8D are explanatory (second) views of the example of the terminal forming method according to the first embodiment.

FIGS. 9A and 9D are explanatory (third) views of the example of the terminal forming method according to the first embodiment.

FIGS. 10A to 10D are explanatory views of two other examples of a terminal forming method.

FIGS. 11A to 11D are other explanatory views of two other examples of the terminal forming method.

FIGS. 12A and 12B are views illustrating an exemplary terminal according to a second embodiment.

FIGS. 13A to 13D are explanatory views of an example of bonding between terminals according to the second embodiment.

FIGS. 14A and 14B are explanatory views of another example of bonding between terminals according to the second embodiment.

FIGS. 15A to 15D are explanatory (first) views of an example of a terminal forming method according to the second embodiment.

FIGS. 16A to 16D are explanatory (second) views of an example of the terminal forming method according to the second embodiment.

FIGS. 17A and 17B are views illustrating an exemplary terminal according to a third embodiment.

FIGS. 18A to 18D are explanatory views of an example of bonding between terminals according to the third embodiment.

FIGS. 19A and 19B are explanatory views of another example of bonding between terminals according to the third embodiment.

FIGS. 20A to 20D are explanatory (first) views of an example of a terminal forming method according to a third embodiment.

FIGS. 21A to 21D are explanatory (second) views of an example of a terminal forming method according to the third embodiment.

FIGS. 22A to 22C are views illustrating another exemplary terminal after a reflow process.

FIG. 23 is a view illustrating an example of a result of evaluation.

### DESCRIPTION OF EMBODIMENTS

When an electrode of an electronic component is bonded with another electrode of another electronic component by a soldering method, a case may occur where a volume of a bonding portion is reduced due to the diffusion and reaction of the electrode component and the solder component formed on the electrode, and thus the bonding portion is broken during the bonding or after the bonding. Even when the barrier layer is formed on the electrode, there is a concern that the solder component may be diffused to a lower electrode along a side surface of the barrier layer and reacted with the electrode to cause a reduction of the volume of the bonding portion and breakage of the bonding portion depending on, for example, the materials of an electrode and a solder, as well as the bonding conditions (e.g., an amount of press of an electronic component, and an amount of solder on the barrier layer).

According to an aspect of the present disclosure, there is provided an electronic component which includes an electrode portion and a solder portion formed on the electrode portion. In the electronic component, the electrode portion includes a first conductive portion and a second conductive portion having different diffusion coefficients with respect to a component of the solder portion and formed on a top surface of the electrode portion, and the solder portion is formed on the first conductive portion and the second conductive portion.

Further, according to another aspect of the present disclosure, there is provided an electronic apparatus including the electronic component and a method of manufacturing the electronic apparatus.

According to a disclosed technique, conductive portions having different diffusion coefficients with respect to the component of the solder portion is provided on the top surface of the electrode portion to cause a preferential diffusion and reaction occur at one of the conductive portions during bonding with a counterpart terminal. As a result, it is possible to suppress the solder portion from being diffused from the top surface to the side surface of the electrode portion. Accordingly, breakage of the bonding portion is suppressed to improve the reliability of connection between the electronic components.

A technology of connection between the electronic components will be described first. For example, as a technology of connecting a semiconductor element (e.g., the semiconductor chip) to a circuit substrate, a wire bonding technology has been known in which the semiconductor chip is mounted on the circuit substrate to connect the terminal of the semiconductor chip with the terminal of the circuit substrate by a wire. Further, as the number of connection terminals increases, a flip chip bonding technology has become utilized in which the semiconductor chip and the circuit substrate are faced with each other to connect the terminals of the semiconductor chip and the circuit substrate.

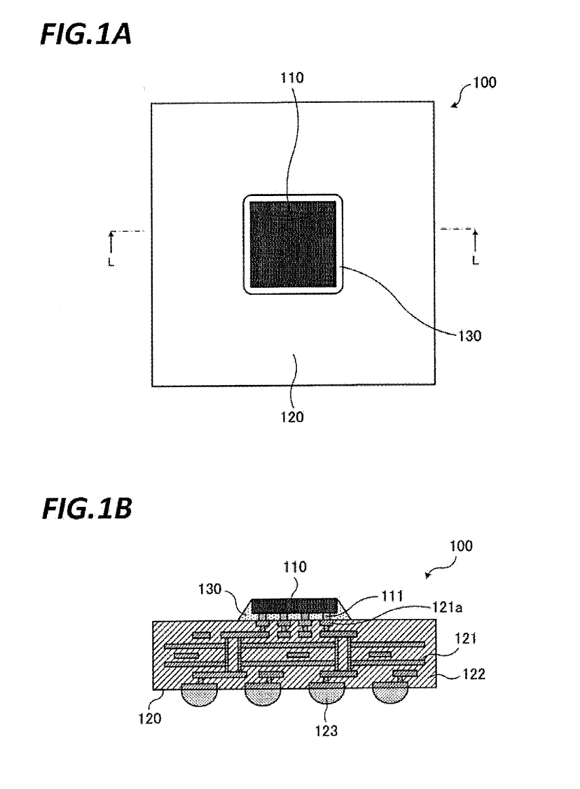

FIG. 1 is a view illustrating an exemplary semiconductor device. FIG. 1 A is a plan view of an example of the semiconductor device and FIG. 1 B is a cross sectional view of the semiconductor device taken along the line L-L. A semiconductor device 100 includes a semiconductor chip 110 and a circuit substrate 120 as illustrated in FIG. 1A and FIG. 1B. The semiconductor chip 110 includes a plurality of connection terminals 111 provided on a surface of the semiconductor chip 110 as illustrated in FIG. 1B. The circuit substrate 120 includes a conductive portion 121 (e.g., wiring, via, through-hole) and an insulating portion 122 provided around the conductive portion 121 as illustrated in FIG. 1B. Electrode terminals 121a are provided at positions that correspond to the position of each connection terminal 111 of the semiconductor chip 110 in the circuit substrate 120. The semiconductor chip 110 is disposed to be opposed with the circuit substrate 120 and each connection terminal 111 is bonded to the corresponding electrode terminal 121a and thus, the semiconductor chip 110 is electrically connected with the circuit substrate 120.

Under-fill materials 130 may be filled between the semiconductor chip 110 and the circuit substrate 120 as illustrated in FIG. 1B. Further, the external connection terminals 123 such as solder balls may be provided on a surface of the circuit substrate 120 opposite to the surface of the semiconductor chip 110 allowing the circuit substrate 120 mounted with the semiconductor chip 110 to be connected with other circuit substrate (e.g., a secondary mounting) using the external connection terminal 123.

Bonding materials such as solder or copper (Cu) are being used widely in the terminal portion in a flip chip bonding technology. In addition to the method using a bump such as the solder ball, the terminal may be formed by a bonding method in which a pillar electrode is formed with, for example, copper (Cu), and a solder is formed on the pillar electrode to bond with a counter-part terminal (e.g., pillar electrode) from a point of view that increases the number of terminals and improves the reliability of connection. As for the solder, lead-free solder which does not contain lead (Pb) has been used considering an environmental effect.

The structure of the terminal including the above-described pillar electrode may be similarly adopted in the terminal of the circuit substrate or the terminal of a semiconductor device (e.g., a semiconductor device package) provided with the semiconductor chip in addition to the terminal of the semiconductor chip.

The diffusion coefficient of tin (Sn), which is a main component of the lead-free solder is high with respect to copper. Therefore, when the solder is melted by heating during the bonding of the terminals, tin (Sn) and copper (Cu) are diffused and reacted with each other and thus, an Inter-Metallic Compound (IMC) containing tin (Sn) and copper (Cu) is formed on the bonding portion between the terminals. When the diffusion and reaction of tin (Sn) and copper (Cu) are progressed by the heating generated during the bonding process or heating generated after the bonding process (e.g., the heating generated during a secondary mounting or the heating caused by the heat generation during the operation of the semiconductor chip), phenomenon such as the reduction of the volume of the bonding portion between the terminals and the erosion of tin (Sn) into the wiring portion of a lower layer of the terminal may occur.

In consideration of such phenomenon, a terminal structure may be used in which material having a lower reactivity with tin (Sn) than copper (Cu) (e.g., having a low diffusion coefficient to tin), such as, for example, a layer of nickel (Ni) is formed as a barrier metal layer on a pillar electrode made of copper in order to suppress the reaction of tin and copper.

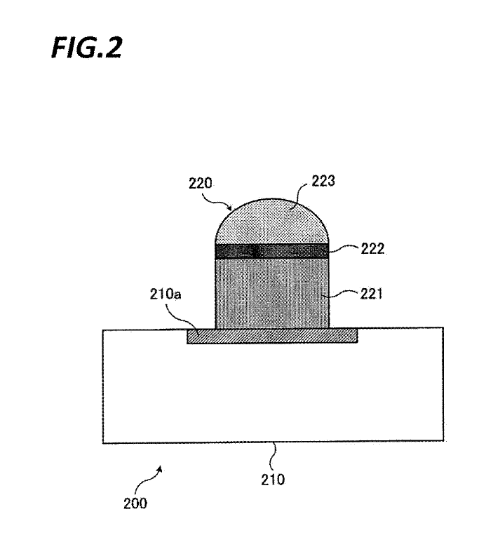

FIG. 2 is a view illustrating an example of a terminal. Here, the structure of the terminal of a semiconductor chip will be described by way of an example. The cross-sections of the principal portions of an exemplary semiconductor chip are diagrammatically illustrated in FIG. 2. The semiconductor chip 200 as illustrated in FIG. 2 includes a terminal 220 protruding from a wiring portion 210a provided on a main body portion 210. Further, a single terminal 220 is exemplified for convenience, but a plurality of terminals 220 may be provided on the main body portion 210 as well. The terminal 220 includes a pillar electrode 221 provided on the wiring portion 210a, a barrier metal 222 provided on the pillar electrode 221, and a solder 223 formed on the barrier metal 222. For example, copper is used in the pillar electrode 221, nickel is used in the barrier metal 222, and material containing tin (Sn) as a main component is used in the solder 223.

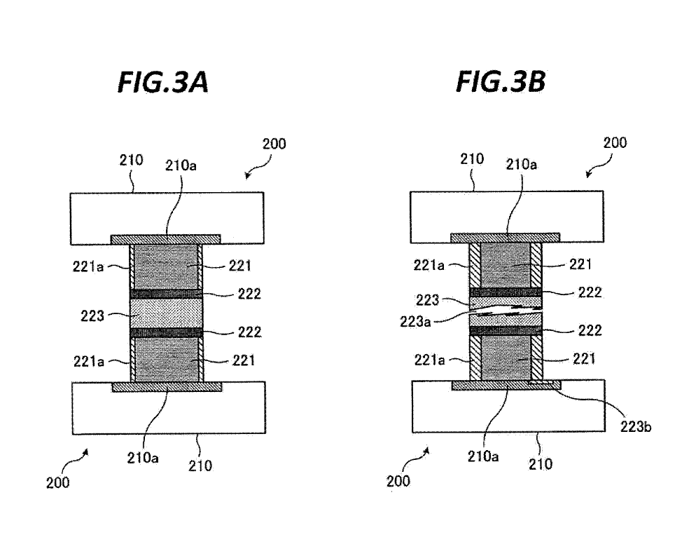

As described above, the solder 223 is formed on the pillar electrode 221 through the barrier metal 222 to suppress the diffusion and reaction of tin (Sn) of the solder 223 and copper of the pillar electrode 221 during bonding or during heating after bonding of the semiconductor chips 200. However, even when the terminal 220 in which the barrier metal 222 is provided on the pillar electrode 221 is adopted, a case where tin (Sn) of the solder 223 is reacted with copper of the pillar electrode 221 may occur as illustrated in FIG. 3.

FIG. 3 is a view illustrating an example of bonding between the terminals. Here, a bonding of the semiconductor chips provided with the terminals as illustrated in FIG. 2 will be described by way an example. FIG. 3A and FIG. 3B illustrate the cross-sections of the principal portions of exemplary semiconductor chips subjected to the bonding, respectively.

When, for example, the semiconductor chips 200 on which the terminals 220 as illustrated in FIG. 2 are provided are bonded with each other, the pillar electrodes 221 on which the barrier metals 222 of a upper and lower semiconductor chips 200 are provided are bonded with each other in such a manner that the solder 223 is interposed between the pillar electrodes 221 as illustrated in FIG. 3A. In this case, tin (Sn) contained in the solder 223 may preferentially diffuse along a side surface of the barrier metal 222 toward a side surface of the pillar electrode 221 made of copper having a diffusion coefficient higher than that of the barrier metal 222 made of nickel (Ni). The diffusion described above may occur more easily in a case where materials are in combination of tin (Sn) and copper (Cu) as illustrated or a case where the solder 223 is diffused from the top surface to the side surface of the barrier metal 222 during bonding. Further, a situation where the solder 223 is diffused from the top surface to the side surface of the barrier metal 222 may occur more easily as an amount of the solder 223 formed on the barrier metal 222 gradually increases before bonding. Further, the situation may occur more easily as an amount of pressure for the semiconductor chip 200 gradually increases during bonding.

When tin (Sn) of the solder 223 is diffused along a side surface of the barrier metal 222 to the side surface of the pillar electrode 221 made of copper and reacted with copper, as illustrated in FIG. 3A, a compound 221a containing tin (Sn) and copper (Cu) may be formed on a lateral side of the pillar electrode 221. When an amount of diffusion of tin (Sn) contained in the solder 223 increases, the amount of reaction with copper (Cu) of the pillar electrode 221 increases and thus, the compound 221a may be formed on a larger range in the lateral side of the pillar electrode 221 as illustrated in FIG. 3B. As described above, when tin (Sn) of the solder 223 is diffused to the side surface of the pillar electrode 221 and consumed in forming the compound 221a at the side surface, an amount of the solder 223 remaining in a space between the pillar electrodes 221 (between the barrier metals 222) opposed to each other decreases. In this case, a broken portion 223a is generated in the solder 223 between the pillar electrodes 221 as illustrated in FIG. 3B, connection failure between the pillar electrodes 221 may occur.

Further, when tin (Sn) diffused from the top surface of the barrier metal 222 to the side surface of the pillar electrode 221 is further diffused to reach the wiring portion 210a under the pillar electrode 221, tin (Sn) is reacted with a component of the wiring portion 210a to erode the wiring portion 210a (e.g., an erosion portion 223b) and thus, there may be a concern that failure in the wiring portion 210a may occur.

A method may be considered in which the diffusion of tin (Sn) of may be suppressed by covering the side surface of the pillar electrode 221 with a film of, for example, a polyimide resin. However, when such a film is not adhered sufficiently to the side surface of pillar electrode 221, it is difficult to achieve necessary suppression of diffusion.

A structure of the terminal 220 including the pillar electrode 221, the barrier metal 222 and the solder 223 as illustrated in FIG. 2 may also be adopted in the terminal of a semiconductor package provided with the semiconductor chip, or in the terminal of the circuit substrate in addition to the terminal of the semiconductor chip. The structure of the terminal 220 may also be adopted in connection between various electronic components, such as, for example, a connection between the semiconductor chip and the circuit substrate, a connection between the semiconductor chip and the semiconductor package, a connection between the semiconductor package and the circuit substrate, a connection between the semiconductor packages, and a connection between the circuit substrates in addition to connection between the semiconductor chips. Generation of the broken portion 223a and erosion of the wiring portion 210a caused by the diffusion of tin (Sn) of the solder 223 described above may also occur in connections between various electronic components that adopt the structure of the terminal 220.

In consideration of above matters, a terminal having a structure described in below as an embodiment is used as the terminal of the electronic components such as the semiconductor chip, the semiconductor package, and the circuit substrate. A first embodiment will be described.

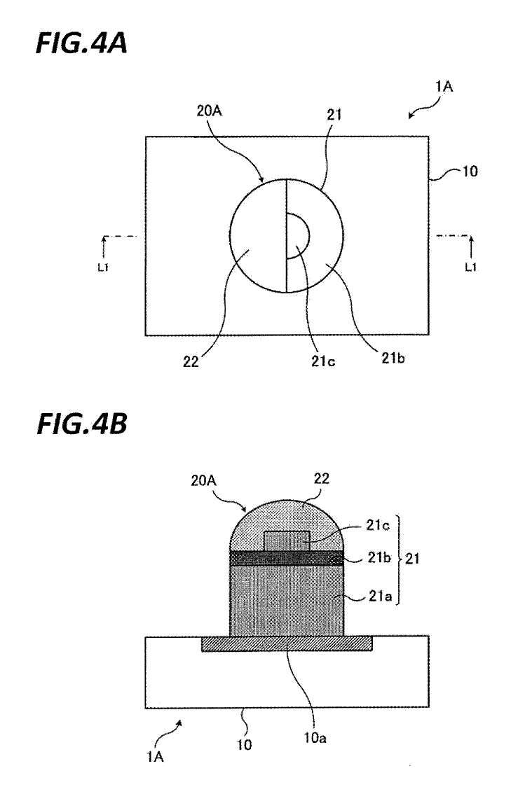

FIG. 4 is a view illustrating an exemplary terminal according to a first embodiment. FIG. 4A is a plan view illustrating the principal portions of an example of an electronic component provided with the terminal according to the first embodiment. FIG. 4B is a cross sectional view illustrating the cross-sections of the principal portions of an example of the electronic component provided with the terminal according to the first embodiment. FIG. 4B is a cross sectional view taken along the line L1-L1 of FIG. 4A. A portion of solder is not illustrated in FIG. 4A for convenience.

An electronic component 1A illustrated in FIG. 4A and FIG. 4B is provided with a terminal 20A protruded from the wiring portion 10a provided on a main body portion 10. Further, a single terminal 20A is illustrated in FIG. 4A for convenience, but a plurality of terminals 20A may be provided on the main body portion 10.

The terminal 20A includes an electrode portion 21 and a solder 22 (e.g., or a solder portion) formed on the electrode portion 21. The electrode portion 21 of the terminal 20A includes a pillar electrode 21a (e.g. a conductive portion) provided on the wiring portion 10a, a barrier metal 21b (e.g., a conductive portion) provided on the pillar electrode 21a, and a protrusion 21c (e.g., a conductive portion) provided on the barrier metal 21b. Material which reacts with a predetermined component contained in the solder 22 to form a compound is used in the protrusion 21c.

The barrier metal 21b is provided to cover the top surface of the pillar electrode 21a. The protrusion 21c is provided on a portion of the top surface of the barrier metal 21b, in this example, on a central portion of the top surface of the barrier metal 21b. The barrier metal 21b and the protrusion 21 are exposed on the top surface of the electrode portion 21, and the solder 22 is formed on the electrode portion 21 to cover the barrier metal 21b and the protrusion 21 exposed on the top surface of the electrode portion 21.

A material having tin (Sn) as the main component is used in the solder 22. Material, such as, for example, copper (Cu) is used in the pillar electrode 21a of the electrode portion 21. Components contained in the solder 22, that is, in this example, materials having different diffusion coefficients with respect to tin (Sn) are used in the barrier metal 21b and the protrusion 21c of the electrode portion 21. Here, material having diffusion coefficient with respect to tin (Sn) which is lower than that of the protrusion 21c is used in the barrier metal 21b. For example, nickel (Ni) is used in the barrier metal 21b and for example, copper (Cu) is used in the protrusion 21c. Herein-below, the terminal 20A using the materials exemplified above will be described by way of an example.

When a diffusion coefficient of copper (Cu) to tin (Sn) is compared with that of nickel (Ni) to tin (Sn) from a value from other documents (e.g., http://diffusion.nims.go.jp/), the diffusion coefficient of copper (Cu) is 2.05×10⁻¹⁰ (m²/sec) and the diffusion coefficient of nickel (Ni) is 1.79×10⁻¹⁰ (m²/sec) at a temperature of 200° C. The diffusion coefficient of copper (Cu) is 6.17×10⁻¹¹ (m²/sec) and the diffusion coefficient of nickel (Ni) is 4.86×10⁻¹¹ (m²/sec) at a temperature of 100° C. A diffusion coefficient of copper (Cu) to tin (Sn) is higher than that of nickel (Ni) to tin (Sn).

As described above, the barrier metal 21b and the protrusion 21c having diffusion coefficient to tin (Sn) higher than that of the barrier metal 21b to tin (Sn) are formed on the top surface of the electrode portion 21 and thus, tin (Sn) contained in the solder 22 is preferentially diffused to and reacted with the protrusion 21c during bonding of other electronic component and the electronic component 1A. Accordingly, diffusion of tin (Sn) of the solder 22 toward the side surface of the pillar electrode 21a may be suppressed.

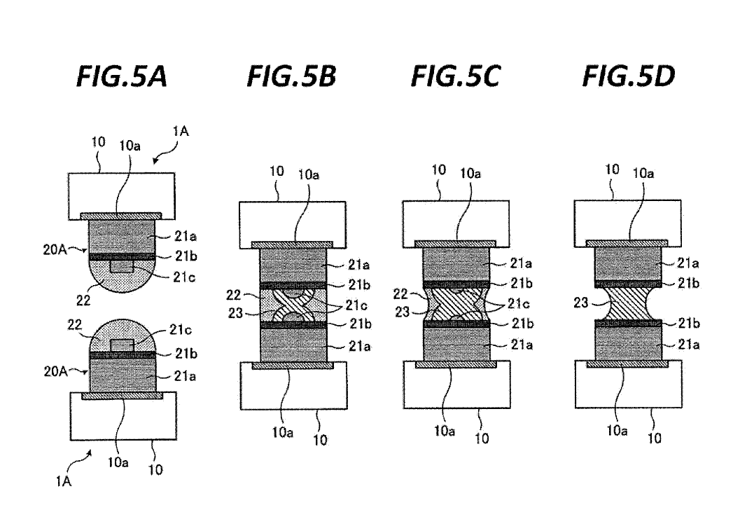

FIG. 5 is a view illustrating an example of bonding between the terminals according to the first embodiment. Here, a bonding of the electronic components 1A provided with the terminal 20A as illustrated in FIG. 4 will be described by way an example. FIGS. 5A, 5B, 5C and 5D illustrate principal portions of an example of the electronic component 1A during bonding.

The terminals 20A are provided on corresponding position of the electronic components 1A to be connected in advance. When the terminals 20A are bonded with each other, the terminal 20A are disposed first to face with each other in the electronic components 1A provided with the terminal 20A as illustrated in FIG. 5A.

Subsequently, the pillar electrodes 21a, on which the barrier metal 21b and the protrusion 21c are formed, of the electronic components 1A are bonded with each other in such a manner that the solder 22 is interposed between the pillar electrodes 21a by pressing the electronic components 1A while heating at a temperature of a melting point or more of the solder 22 as illustrated in FIG. 5B. In this case, tin (Sn) contained in the solder 22 is preferentially diffused to and reacted with the protrusion 21c made of copper (Cu) having higher diffusion coefficient among the barrier metal 21b made of nickel (Ni) and the protrusion 21c made of copper (Cu) that contact with the solder 22 to form a compound 23. As the reaction of tin (Sn) of the solder 22 with copper (Cu) of the protrusion 21c is progressed, the compound 23 is continued to grow as illustrated in FIG. 5C.

When the compound 23 is growing, a volume contraction of the bonding portion between the pillar electrodes 21a (e.g., between the barrier metals 21b) occurs as the compound grows as illustrated in FIG. 5C. Similarly to this example, in a case where copper (Cu) is used in the protrusion 21c, when copper (Cu) and tin (Sn) are reacted with each other to form the compound 23, crystals of the compound are arranged densely and thus, the volume contraction of the bonding portion between the pillar electrodes 21a occurs. The density of copper (Cu) is 8.9 g/cm², and the density of tin (Sn) is 7.3 g/cm². When such a copper (Cu) and tin (Sn) are reacted with each other, a copper-tin compound (Cu₆Sn₅) is formed as the compound 23. When a mass ratio of copper (Cu) to tin (Sn) contained in the compound 23 is predicted from a metal binary phase diagram of tin (Sn) and copper (Cu), the mass ratio of copper (Cu) to tin (Sn) is about 40:60. The density of the compound 23 is 8.28 g/cm², and during forming the compound 23, the volume of the compound 23 is reduced by about 5%. When the protrusion 21c is formed on the central portion of the barrier metal 21b, as the compound 23 grows, as illustrated in FIG. 5C and further in FIG. 5D, a volume contraction of the bonding portion between the pillar electrodes 21a is continued toward the central portion of the barrier metal 21b.

As described above, the protrusion 21c made of copper (Cu) is formed on the central portion of the barrier metal 21b made of nickel (Ni) and thus, tin (Sn) of the solder 22 is preferentially diffused to and reacted with the protrusion 21c to form the compound 23. Further, when the compound 23 is formed, a volume contraction of the bonding portion between the pillar electrodes 21a occurs toward the central portion of the barrier metal 21b. Accordingly, diffusion of tin (Sn) of the solder 22 along the side surface to the side surface of the pillar electrode 21 may be suppressed by stopping diffusion flow of the solder 22 at a space between the opposing pillar electrodes 21. Further, excessive reaction of the solder 22 and the pillar electrode 21a is suppressed by the barrier metal 21b. As a result, the solder 22 is reduced in the bonding portion between the opposing pillar electrodes 21a and thus, generation of the broken portion may be suppressed.

In the terminal 20A in which the protrusion 21c made of copper (Cu) is formed on the central portion of the barrier metal 21b made of nickel (Ni), when all of copper (Cu) of the protrusion 21c is consumed in forming the compound 23 with tin (Sn) of the solder 22, the forming of the compound 23 is not continued after the consumption. Therefore, excessive diffusion of tin (Sn) of the solder 22 is suppressed.

The terminal 20A is provided on the electronic components 1A as described above to implement an electronic apparatus in which the electronic components 1A are connected with high reliability. In the meantime, in the electronic apparatus, all of the solder 22 may not necessarily be changed into the compound to form a bonding state as illustrated in FIG. 5D and may be changed into the compound to form the bonding states as illustrated in FIG. 5B and FIG. 5C. In the electronic apparatus having the bonding states as illustrated in FIG. 5B and FIG. 5C, when being heated at later, the diffusion of tin (Sn) to the side surface of the pillar electrode 21a and breakage of the bonding portion may be suppressed due to the preferential diffusion of tin (Sn) of the solder 223 to the protrusion 21c and due to the volume contraction during forming the compound 23.

While bonding between the electronic components 1A provided with the terminals 20A is described by way of an example, when the electronic component 1A provided with the terminal 20A and other electronic component provided with a terminal provided with a structure different from the terminal 20A are bonded, the effects as described above may be obtained.

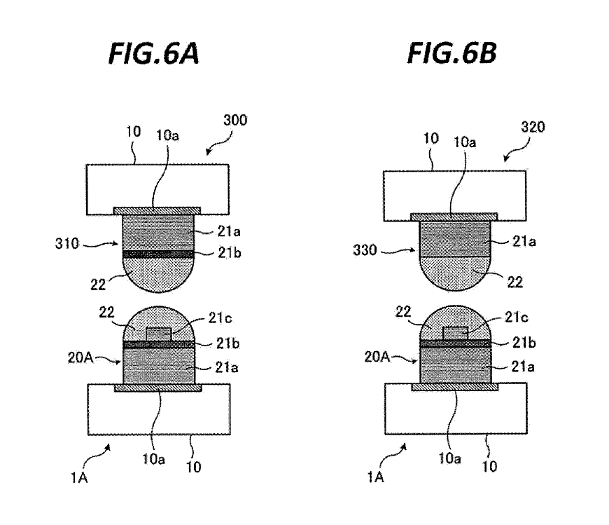

FIG. 6 is a view explaining another example of bonding between the terminals according to the first embodiment. In an example of FIG. 6A, the electronic components 1A is bonded with an electronic components 300 which is different from the electronic components 1A. The electronic components 1A is provided with the terminal 20A which includes the pillar electrode 21a, the barrier metal 21b and the protrusion 21c as described above. In the meantime, the electronic components 300 is provided with the terminal 310 which includes the pillar electrode 21a and the barrier metal 21b, and does not include the protrusion 21c. A preferential diffusion of tin (Sn) of the solder 22 to the protrusion 21c and a volume contraction according to the formation of the compound 23 are also generated in bonding between the terminal 20A of the electronic components 1A and the terminal 310 of the electronic components 300, similarly to the above-description. Accordingly, the diffusion of tin (Sn) to the side surface of the pillar electrode 21a and the breakage of the bonding portion between the pillar electrodes 21a may be suppressed.

In an example of FIG. 6B, the electronic components 1A is bonded with an electronic component 320 which is different from the electronic components 1A. The electronic components 1A is provided with the terminal 20A which includes the pillar electrode 21a, the barrier metal 21b and the protrusion 21c, and the electronic components 320 is provided with the terminal 330 which does not include the barrier metal 21b and the protrusion 21c. In the meantime, the terminal 330 may adopt various shapes, such as for example, a pillar electrode, a pad electrode and a wiring portion. The preferential diffusion of tin (Sn) of the solder 22 to the protrusion 21c and the volume contraction according to the formation of the compound 23 are also generated in bonding between the terminal 20A of the electronic components 1A and the terminal 330 of the electronic components 320. Accordingly, the diffusion of tin (Sn) to the side surface of the pillar electrode 21a or the terminal 330 and the breakage of the bonding portion between the pillar electrodes 21a may be suppressed.

The terminal 20A as described above is provided on the electronic component 1A to implement an electronic apparatus in which the electronic component 1A and other electronic component is connected with high reliability. The method of forming the terminal 20A according to the first embodiment as described above will be described next.

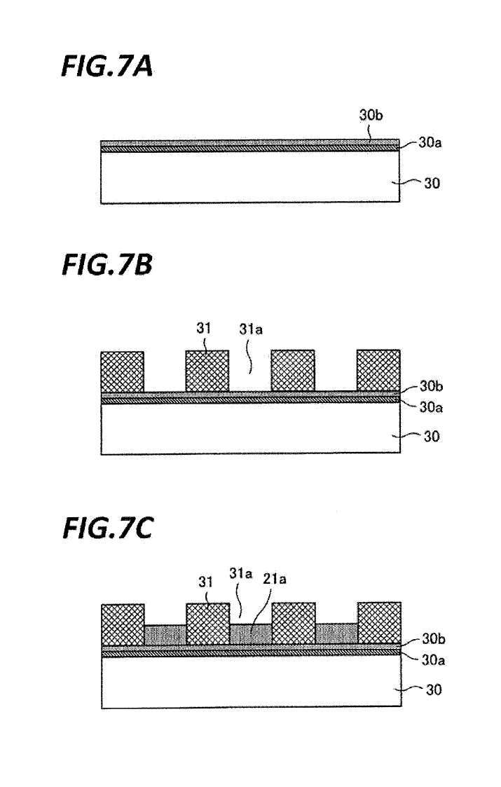

FIG. 7 to FIG. 9 are views explaining an example of a terminal forming method according to the first embodiment. The cross sectional views of principal portions in each process of a terminal forming method are diagrammatically illustrated in FIG. 7 to FIG. 9. The substrate 30 in which the terminal 20A is formed is prepared first as illustrated in FIG. 7A. One or plural main body portions 10, though not illustrated herein for convenience, of the electronic components 1A are formed on the substrate 30. That is, there is a case where the substrate 30 itself is the main body portion 10 of a single electronic components 1A (e.g., a circuit substrate) or the main body portions 10 of a plurality of the electronic components 1A included in the substrate 30 (e.g., a wafer in which plural semiconductor chips are formed). Further, when the main body portions 10 of a plurality of the electronic components 1A are included in the substrate 30, the plurality of the electronic components 1A are separated into an electronic component 1A after the terminal 20A is formed on each main body portion 10.

An adhesion layer 30a and a seed layer 30b are formed on the substrate 30 prepared as illustrated in FIG. 7A. For example, a titan (Ti) layer having a thickness of 100 nm is formed as the adhesion layer 30a and a copper (Cu) layer having a thickness of 500 nm is formed as the seed layer 30b. The adhesion layer 30a and the seed layer 30b may be formed using a sputtering method.

Subsequently, the resist 31 is coated, and exposing and developing is performed on the resist 31 to form an opening portion 31a at an area in which the terminal 20A of the substrate 30 is formed (e.g., an area corresponding to the wiring portion 10a of the main body portion 10) as illustrated in FIG. 7B. For example, the opening portion 31a having a diameter of 10 μm is formed.

Subsequently, copper (Cu) is plated using the seed layer 30b as a power-feeding layer to form the pillar electrode 21a within the opening portion 31a of the resist 31 as illustrated in FIG. 7B using an electrolytic plating method. For example, the pillar electrode 21a made of copper (Cu) having a height (thickness) of 5 μm is formed within the opening portion 31a of the resist 31.

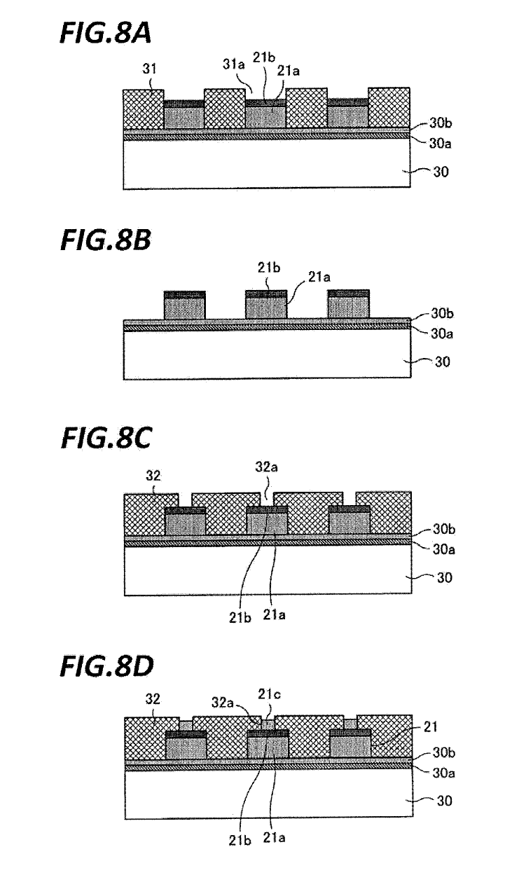

Subsequently, the barrier metal 21b is formed on the pillar electrode 21a within the opening portion 31a of the resist 31 as illustrated in FIG. 8A using an electrolytic plating method. For example, a nickel (Ni) layer having a height (thickness) of 3 μm as the barrier metal 21b is formed on the pillar electrode 21a 31.

The resist 31 is peeled off after forming the barrier metal 21b as illustrated in FIG. 8B. Subsequently, as illustrated in FIG. 8C, the resist 32 is coated, and an exposing process and a developing process are performed on the resist 32 to form an opening portion 32a on a central portion of the barrier metal 21b. For example, the opening portion 32a having a diameter of 8 μm is formed on the resist 32.

Subsequently, the protrusion 21c is formed on the barrier metal 21b within the opening portion 32a of the resist 32 as illustrated in FIG. 8D using an electrolytic plating method. For example, a copper (Cu) layer having a height (thickness) of 2 μm is formed on the barrier metal 21b as the protrusion 21c. Accordingly, the electrode portion 21 in which the barrier metal 21b is formed on the pillar electrode 21a and the protrusion 21c is formed on the barrier metal 21b, is formed.

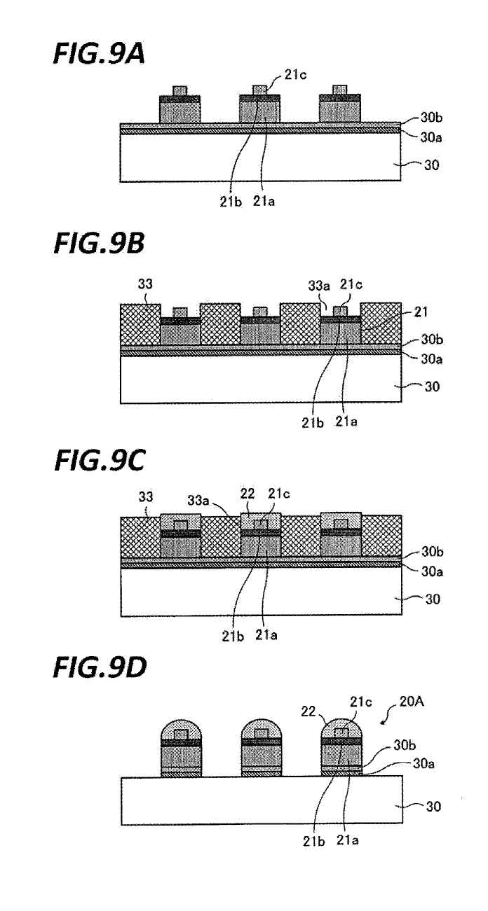

The resist 32 is peeled off after forming the protrusion 21c as illustrated in FIG. 9A. Subsequently, as illustrated in FIG. 9B, the resist 33 is coated and an exposing process and a developing process are performed on the resist 33 to form an opening portion 33a on an area of the electrode portion 21.

Subsequently, a solder 22 is formed on the protrusion 21c and the barrier metal 21b within the opening portion 33a of the resist 33 as illustrated in FIG. 9C using an electrolytic plating method. For example, a tin-silver (SnAg) solder having a thickness of 3.5 μm is formed as the solder 22. Further, a volume of the solder 22 to be formed may be set to a volume which is about 1.85 times or less of a volume of the protrusion 21c in order for all tin (Sn) contained in the solder 22 to be reacted with copper. In this case, a size of copper of the protrusion 21c is defined as a circular column having a thickness of 2 μm and a diameter of 8 μm, and a desirable thickness of the solder is about 3.65 μm or less.

After forming the solder 22, as illustrated in FIG. 9D, the resist 33 is peeled off, and the seed layer 30b and the adhesion layer 30a exposed after the resist 33 is peeled off are removed by etching. Reflow process is performed after the seed layer 30b and the adhesion layer 30a are etched to form the solder 22 having a rounded shape as illustrated in FIG. 9D. In the meantime, the reflow process of FIG. 9D may be omitted.

The terminal 20A in which the solder 22 is formed to cover the barrier metal 21b formed on the pillar electrode 21a and the protrusion 21c formed on the central portion of the barrier metal 21b is formed according to the processes of FIG. 7A to FIG. 9D.

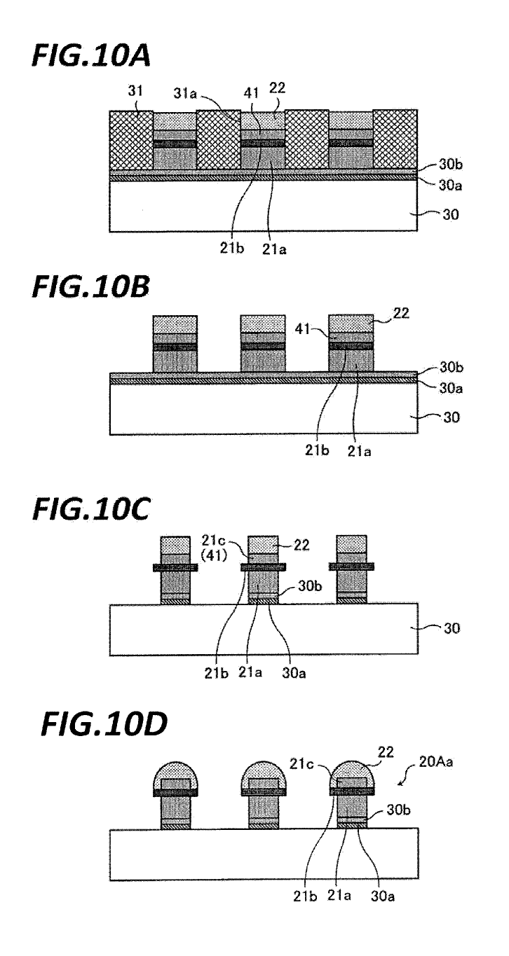

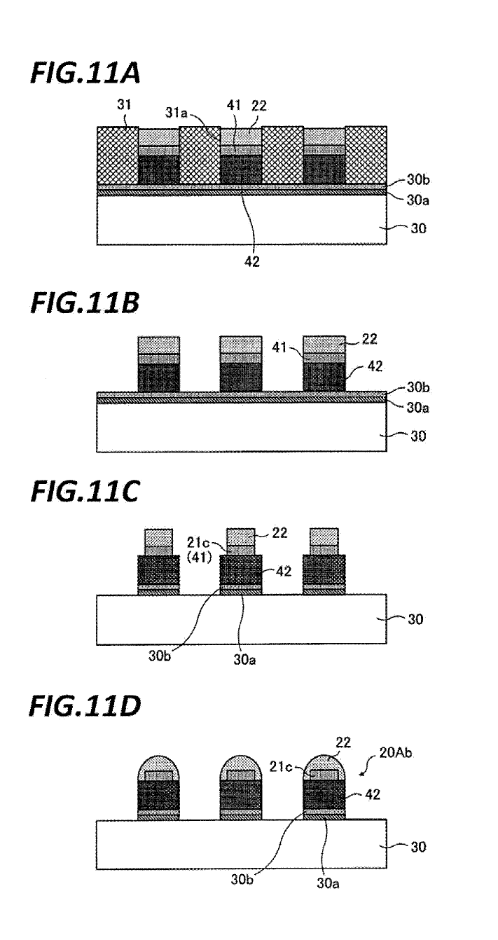

A terminal formed according to a method illustrated in FIG. 10 and in FIG. 11 may be used as a terminal in which a protrusion having higher diffusion coefficient to a solder component is formed on the barrier metal, and a solder is formed to cover the barrier metal and the protrusion similarly to the terminal 20A according to the first embodiment.

FIG. 10 is an explanatory view of another example of a terminal forming method. The cross sectional views of principal portions in each process of a terminal forming method are diagrammatically illustrated in FIG. 10. In an example of FIG. 10, the processes illustrated in FIG. 7A to FIG. 7C are performed first. Thereafter, as illustrated in FIG. 10A, the barrier metal 21b is formed, the plating layer 41 for forming the protrusion 21c is formed on the barrier metal 21b, and the solder 22 is formed on the plating layer 41 using an electrolytic plating method. For example, a nickel (Ni) layer having a thickness of 3 μm is formed as the barrier metal 21b, a copper (Cu) layer having a thickness of 2 μm is formed as the plating layer 41, and a tin-silver (Sn—Ag) solder layer having a thickness of 3.5 μm is formed as the solder 22.

Subsequently, the resist 31 is peeled off as illustrated in FIG. 10B, and the seed layer 30b and the adhesion layer 30a exposed after the resist 31 is peeled off are removed by etching as illustrated in FIG. 10C. In this case, the seed layer 30b is removed by wet etching. In the wet etching, an etching rate of the plating layer 41 made of copper (Cu) is higher as compared to the etching rate of the barrier metal 21b made of nickel (Ni). The diameter of the plating layer 41 becomes narrower than that of the barrier metal 21b, as a result, the plating layer 41 having a narrowed diameter, that is, the protrusion 21c, is formed on the central portion of the barrier metal 21b due to the difference in an etching rate between nickel (Ni) and copper (Cu).

An etching process of the pillar electrode 21a is also progressed during the formation of the protrusion 21c by the wet etching. Further, the etching of the solder 22 may also be progressed during formation of the protrusion 21c by the wet etching. Therefore, the diameter of the pillar electrode 21a and the diameter of the solder 22 may also become narrower than that of the barrier metal 21b as illustrated in FIG. 10C.

Reflow process is performed after the protrusion 21c is formed to form the solder 22 having a rounded shape as illustrated in FIG. 10D. In the meantime, the reflow process of FIG. 10D may be omitted.

The terminal 20Aa in which the solder 22 is formed to cover the barrier metal 21b and the protrusion 21c formed on the central portion of the barrier metal 21b is formed according to the processes of FIG. 7A to FIG. 7C and FIG. 10A to FIG. 10D.

FIG. 11 is an explanatory view of another example of a terminal forming method. Cross sectional views of principal portions in each process of a terminal forming method are diagrammatically illustrated in FIG. 11. In an example of FIG. 11, the processes illustrated in FIG. 7A to FIG. 7C are performed first. Thereafter, as illustrated in FIG. 11A, the electrode layer 42 is formed, the plating layer 41 for forming the protrusion 21c is formed on the electrode layer 42, and the solder 22 is formed on the plating layer 41 using an electrolytic plating method. For example, a nickel (Ni) layer having a height (thickness) of 8 μm is formed as the electrode layer 42, a copper (Cu) layer having a thickness of 2 μm is formed as the plating layer 41, and a tin-silver (Sn—Ag) solder layer having a thickness of 3.5 μm is formed as the solder 22. The electrode layer 42 made of nickel (Ni) serves as a pillar electrode and a barrier metal.

Subsequently, the resist 31 is peeled off as illustrated in FIG. 11B, and the seed layer 30b and the adhesion layer 30a exposed after the resist 31 is peeled off are removed by etching as illustrated in FIG. 11C. In this case, the seed layer 30b is removed by wet etching. In the wet etching, an etching rate of the plating layer 41 made of copper is higher compared an etching rate of the barrier metal 21b made of nickel. The diameter of the plating layer 41 becomes narrower than that of the barrier metal 21b using a difference in an etching rate between nickel (Ni) and copper (Cu) in the wet etching. Accordingly, the plating layer 41 having a narrowed diameter, that is, the protrusion 21c is formed on the central portion of the electrode layer 42.

An etching of the solder 22 is also progressed during the protrusion 21c is formed by the wet etching. Further, the etching of the solder 22 may also be progressed during the protrusion 21c is formed by the wet etching. Therefore, the diameter of the solder 22 may become narrower than that of the electrode layer 42 as illustrated in FIG. 11C.

A reflow process is performed after the protrusion 21c is formed to form the solder 22 having a rounded shape as illustrated in FIG. 11D. Further, the reflow process of FIG. 10D may be omitted.

The terminal 20Ab in which the solder 22 is formed to cover the electrode layer 42 which serves as a pillar electrode and a barrier metal, and cover the protrusion 21c formed on the central portion of the electrode layer 42, is formed according to the processes of FIG. 7A and FIG. 7B and FIG. 11A to FIG. 11D.

The terminal 20A, the terminal 20Aa and the terminal 20Ab as described above may be made to have a circular shape or a substantially circular shape when viewed from a top surface. In addition, the terminal 20A, the terminal 20Aa and the terminal 20A may be made to have an elliptical shape or a substantially elliptical shape, a quadrangular shape or a substantially quadrangular shape or a triangular shape or a substantially triangular shape when viewed from a top surface.

Further, though the protrusion 21c is formed on the central portion of the barrier metal 21b and the electrode layer 42 in the terminal 20A, the terminal 20Aa and the terminal 20Ab as described above, the protrusion 21c may not be formed on the central portion of the barrier metal 21b and the electrode layer 42. When the protrusion 21c is formed at an outer side than the central portion of the barrier metal 21b and the electrode layer 42, the effect of preferential diffusion of tin (Sn) of the solder 22 to the protrusion 21c and the volume contraction of the bonding portion toward the protrusion 21c may be obtained during bonding. Accordingly, the diffusion of tin (Sn) to the side surface of, for example, the pillar electrode 21a and breakage of the bonding portion may be suppressed.

Further, the terminal 20A, the terminal 20Aa and the terminal 20Ab as described above include the pillar electrode 21a made of copper (Cu), the barrier metal 21b made of nickel (Ni), the protrusion 21c made of copper (Cu) and the electrode, which serves as a pillar electrode, made of nickel (Ni) as elements. Here, the pillar electrode 21a made of copper (Cu) and the protrusion 21c made of copper (Cu) include the pillar electrode 21a and the protrusion 21c of which major components are copper (Cu) in addition to the pillar electrode 21a made of pure copper (Cu) and the protrusion 21c made of pure copper (Cu). The barrier metal 21b made of nickel (Ni) and the electrode layer 42 made of nickel (Ni) include the barrier metal 21b of which major component is nickel (Ni) and the electrode layer 42 of which major component is nickel (Ni) in addition to the barrier metal 21b made of pure nickel (Ni) and the electrode layer 42 made of pure nickel (Ni).

Further, a combination of materials used in the protrusion 21c and the barrier metal 21b and the electrode layer 42 is not limited to the combination of copper (Cu) (e.g., including material of which major component is copper (Cu)) and nickel (Ni) (e.g., including material of which major component is nickel (Ni)) as described above. A component of materials to be used in the solder 22 is needed to have a diffusion coefficient which is larger for the protrusion 21c and smaller for the barrier metal 21b and the electrode layer 42.

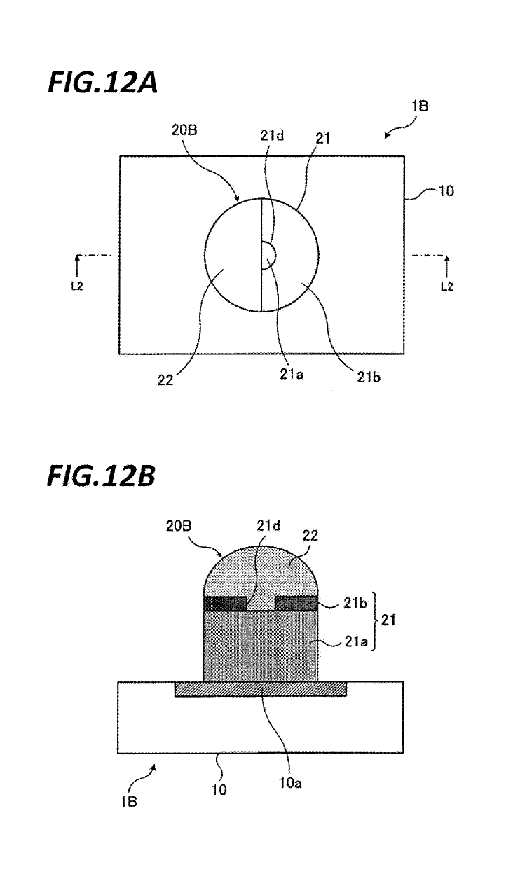

A second embodiment will be described next. FIG. 12 is a view illustrating an example of a terminal according to the second embodiment. FIG. 12A is a plan view illustrating principal portions of an example of the electronic components provided with the terminal according to the second embodiment. FIG. 12B is a cross sectional view illustrating principal portions of an example of the electronic component provided with the terminal according to the second embodiment. FIG. 12B is a cross sectional view taken along the line L1-L1 of FIG. 12A. A portion of solder is not illustrated in FIG. 412 for convenience.

An electronic components 1B illustrated in FIG. 12A and FIG. 12B is provided with a terminal 20B protruded from the wiring portion 10a provided on the main body portion 10. Further, a single terminal 20B is illustrated in FIG. 12A for convenience, but a plurality of terminals 20B may be provided on the main body portion 10.

The terminal 20B includes an electrode portion 21 and a solder 22 (e.g., a solder portion) formed on the electrode portion 21. The electrode portion 21 includes a pillar electrode 21a (e.g. a conductive portion) provided on the wiring portion 10a, a barrier metal 21b (e.g., a conductive portion) provided on the pillar electrode 21a. An opening portion 21d which reaches the pillar electrode 21a below the barrier metal 21b is formed on the barrier metal 21b. The opening portion 21d is formed on the central portion of the barrier metal 21b in this example. The barrier metal 21b and the pillar electrode 21a of the opening portion 21d are exposed on the top surface and the solder 22 is formed to cover the top surface the electrode portion 21 of the electrode portion 21, and the exposed barrier metal 21b and the pillar electrode 21a.

Materials having tin (Sn) as the main component is used in the solder 22. Materials, such as for example, copper (Cu) is used in the pillar electrode 21a. A component contained in the solder 22, that is, in this example, material having a diffusion coefficient with respect to tin (Sn) which is lower than that of the pillar electrode 21a are used in the barrier metal 21b of the electrode portion 21. Herein-below, the terminal 20B using materials exemplified as above will be described by way of an example.

As described above, in the terminal 20B, an opening portion 21d is formed in the barrier metal 21b made of nickel (Ni), the barrier metal 21b and the pillar electrode 21a made of copper (Cu) having higher diffusion coefficient with respect to tin (Sn) are exposed on the top surface the electrode portion 21d from the opening portion 21d of the barrier metal 21b, and the barrier metal 21b and the pillar electrode 21a are covered with the solder 22. Accordingly, during the bonding process of the electronic component 1B with other electronic component, tin (Sn) of the solder 22 is preferentially diffused to and reacted with the pillar electrode 21a, which is made of copper (Cu), of the opening portion 21d, and thus, the diffusion of tin (Sn) to the side surface of the pillar electrode 21a may be suppressed.

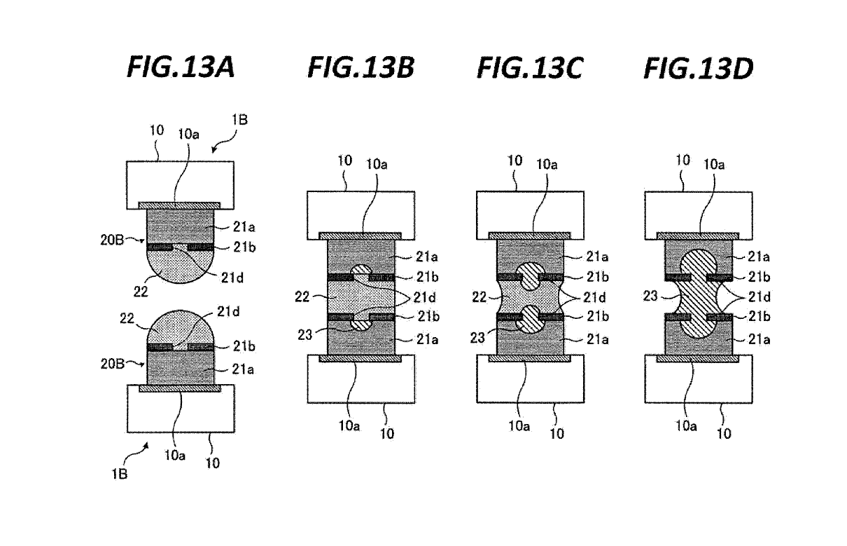

FIG. 13 is a view illustrating an example of bonding between the terminals according to the second embodiment. Here, the bonding between the electronic components 1B provided with the terminals 20B as illustrated in FIG. 12 will be described by way an example. FIG. 13A to FIG. 13D illustrate the cross sections of principal portions of an example of the electronic component 1B during a bonding process.

The terminals 20B are provided on corresponding position of the electronic components 1B to be connected in advance. When the terminals 20B are bonded with each other, the terminals 20B are disposed first to face with each other in the electronic components 1B provided with the terminal 20B as illustrated in FIG. 13A.

Subsequently, the pillar electrodes 21a, on which the barrier metal 21b having an opening portion 21d is formed, of the electronic components 1A are bonded with each other in such a manner that the solder 22 is interposed between the pillar electrodes 21a by pressing the electronic components 1A while heating at a temperature of a melting point or more of the solder 22 as illustrated in FIG. 13B. In this case, tin (Sn) contained in the solder 22 is preferentially diffused to and reacted with the pillar electrodes 21a made of copper (Cu) having higher diffusion coefficient among the barrier metal 21b made of nickel (Ni) and the pillar electrodes 21a made of copper (Cu) of the opening portion 21d that contact with the solder 22 to form a compound 23. As the reaction of tin (Sn) of the solder 22 with copper of the pillar electrodes 21a of the opening portion 21d is progressed, the compound 23 is continued to grow as illustrated in FIG. 13C.

When the compound 23 is growing, crystals are densely arranged as the compound grows and thus, the volume contraction of the bonding portion between the pillar electrodes 21a (between the barrier metals 21b) occurs as illustrated in FIG. 13C. When the opening portion 21d is formed on the central portion of the barrier metal 21b, as the compound 23 is grown, the volume contraction of the bonding portion between the pillar electrodes 21a is progressed toward the central portion of the barrier metal 21b as illustrated in FIG. 13C and further FIG. 13D.

As described above, the opening portion 21d which reaches the pillar electrode 21a made of copper (Cu) is formed on the central portion of the barrier metal 21b made of nickel (Ni) and thus, tin (Sn) of the solder 22 is preferentially diffused to and reacted with the pillar electrode 21a of the opening portion 21d to form the compound 23. Further, when the compound 23 is formed, the volume contraction in the bonding portion between the opposing pillar electrodes 21a occurs. Accordingly, diffusion of tin (Sn) of the solder 22 along the side surface of the barrier metal 21b to the side surface of the pillar electrode 21 may be suppressed by stopping the diffusion flow of the solder 22 at a portion between the pillar electrodes 21. Further, excessive reaction of the solder 22 and the pillar electrode 21a is suppressed by the barrier metal 21b. As a result, the solder 22 of the bonding portion between the opposing pillar electrodes 21a is reduced and thus, the generation of the broken portion may be suppressed.

In the terminal 20B in which the opening portion 21d reaching the pillar electrode 21a is formed on the central portion of the barrier metal 21b, an amount of copper (Cu) which is enough for all tin (Sn) of the solder 22 is changed into the compound 23, may be supplied from the pillar electrode 21a according to bonding conditions (e.g., temperature or time during bonding). Therefore, the bonding portion in which all tin (Sn) of the solder 22 are changed into the compound 23 may bond the pillar electrodes 21a that are opposed to each other, and thus, the problems such as the generation of pore or breakage portion caused by the diffusion of the remaining solder 22 in the bonding portion may also be suppressed in a heating environment after bonding.

The terminal 20B described above is provided on the electronic components 1B to implement an electronic apparatus in which the electronic components 1B are connected with high reliability. Further, in the electronic apparatus, all of the solder 22 may not necessarily be changed into the compound to form a bonding state as illustrated in FIG. 13D and may be changed into the compound to form the bonding state as illustrated in FIG. 13B and FIG. 13C. In the electronic apparatus having the bonding state as illustrated in FIG. 13B and FIG. 13C, when being heated later, the diffusion of tin (Sn) to the side surface of the pillar electrode 21a and breakage of the bonding portion may be suppressed due to the preferential diffusion of tin (Sn) to the pillar electrode 21a of the opening portion 21d and the volume contraction during forming the compound 23.

While bonding between the electronic components 1B provided with the terminals 20B is described by way of an example, the effect as described above may also be obtained when the electronic component 1B provided with the terminal 20B and other electronic component provided with a terminal having a structure different from the terminal 20B are bonded.

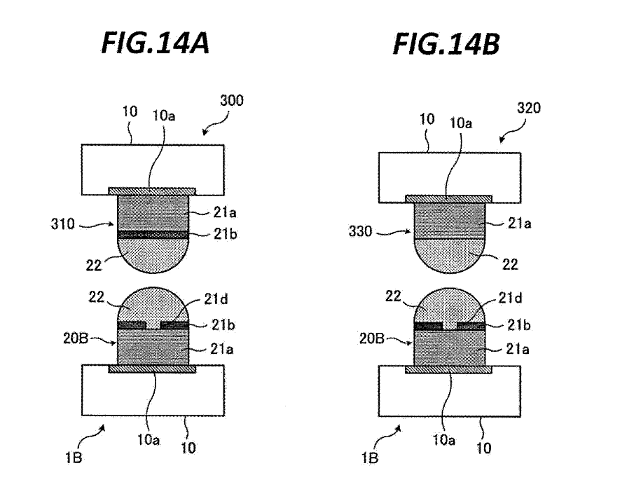

FIG. 14 is an explanatory view of another example of bonding between the terminals according to the second embodiment. In an example of FIG. 14A, the electronic component 1B is bonded with an electronic component 300 which is different from the electronic component 1A. The electronic component 300 is provided with the terminal 310 which includes the pillar electrode 21a and the barrier metal 21b (e.g., which does not include the opening portion 21d). A preferential diffusion of tin (Sn) of the solder 22 to the pillar electrode 21a of the opening portion 21d and a volume contraction according to the formation of the compound 23 are also generated in bonding between the terminal 20B of the electronic component 1A and the terminal 310 of the electronic components 300. Accordingly, the diffusion of tin (Sn) to the side surface of the pillar electrode 21a and the breakage of the bonding portion between the pillar electrodes 21a may be suppressed.

In an example of FIG. 14B, the electronic component 1B is bonded with an electronic component 320 which is different from the electronic component 1B. The electronic component 320 is provided with the terminal 330 (e.g., the pillar electrode, the barrier metal and the wiring portion). A preferential diffusion of tin (Sn) of the solder 22 to the pillar electrode 21a of the opening portion 21d and a volume contraction according to formation of the compound 23 are also generated in bonding between the terminal 20B of the electronic components 1A and the terminal 330 of the electronic components 320. Accordingly, the diffusion of tin (Sn) to the side surface of the pillar electrode 21a or the terminal 330 and the breakage of the bonding portion between the pillar electrodes 21a may be suppressed.

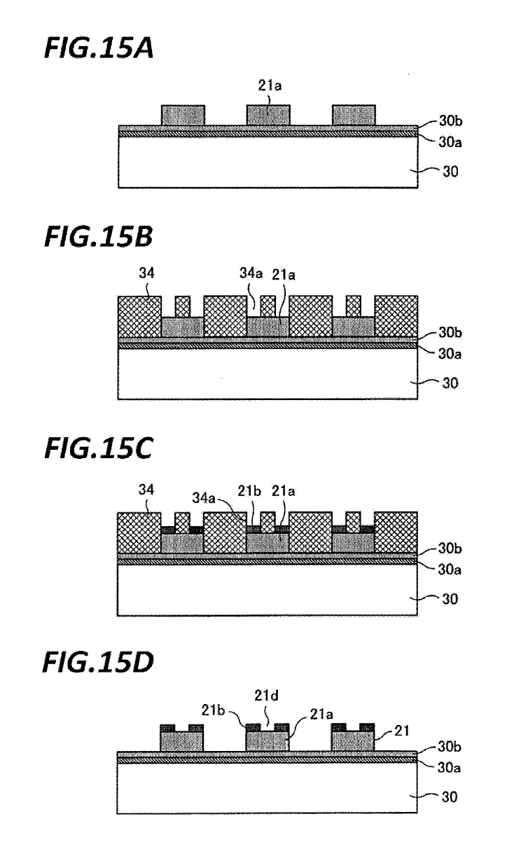

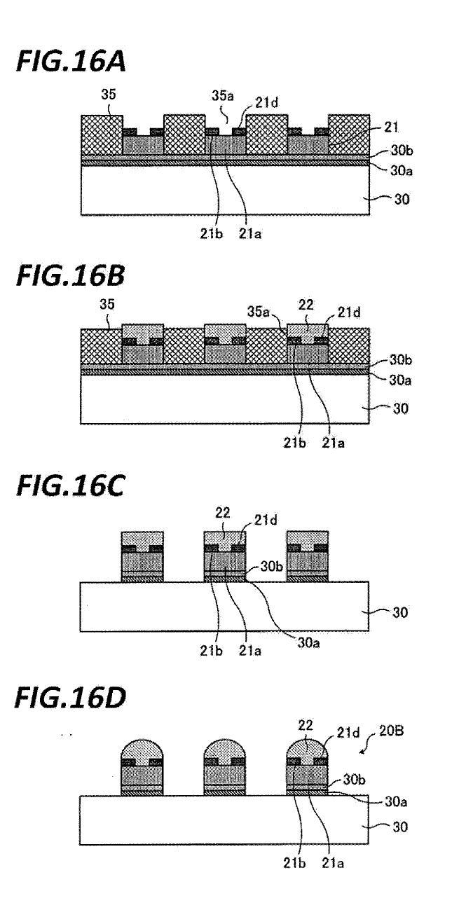

The terminal 20B as described above is provided on the electronic component 1B to implement an electronic apparatus in which the electronic components 1B and other electronic components is connected with high reliability. The method of forming the terminal 20B according to the second embodiment as described above will be described next. Further, the processes of FIG. 7A to FIG. 7C described in the first embodiment may be the same in the forming of the terminal 20B according to the second embodiment. Here, the processes after FIG. 7C will be described reference to FIG. 15 and FIG. 16.

FIG. 15 and FIG. 16 are explanatory views of an example of a terminal forming method according to the second embodiment. The cross sectional views of principal portions in each process of a terminal forming method are diagrammatically illustrated in FIG. 15 and FIG. 16. First, the resist 31 used in forming the pillar electrode 21a is peeled off as illustrated in FIG. 15A after performing the processes of FIG. 7A to FIG. 7C.

Subsequently, the resist 31 is coated, and an exposing process and a developing process are performed on the resist 31 to form a resist 34 covering the peripheral portion and the central portion of the pillar electrode 21a to form an opening portion 34a having a planar doughnut shape on the pillar electrode 21a. For example, the opening portion 31a having a diameter of 10 μm is formed at the central portion of the pillar electrode 21a.

Subsequently, the barrier metal 21b is formed on the pillar electrode 21a within the opening portion 34a as illustrated in FIG. 15C using an electrolytic plating method. For example, a nickel (Ni) layer having a height (thickness) of 3 μm as the barrier metal 21b is formed on the pillar electrode 21a.

The resist 34 is peeled off after forming the barrier metal 21b as illustrated in FIG. 15D. Accordingly, the electrode portion 21 on which the barrier metal 21b having the opening portion 21d which is formed on the central portion of the barrier metal is formed on the pillar electrode 21a.

Subsequently, as illustrated in FIG. 16A, resist material is coated, and an exposing process and a developing process are performed on the resist material to form a resist 35 having an opening portion 35a on an area of the electrode portion 21. Subsequently, a solder 22 is formed on of the pillar electrode 21a of the opening portion 21d and the barrier metal 21b within the opening portion 33a of the resist 33 as illustrated in FIG. 16B using an electrolytic plating method. For example, a tin-silver (Sn—Ag) solder having a thickness of 3.5 μm is formed as the solder 22.

After forming the solder 22, the resist 35 is peeled off, and the seed layer 30b and the adhesion layer 30a exposed after the resist 35 is peeled off are removed by etching as illustrated in FIG. 16C. Then, a reflow process is performed to form the solder 22 having a rounded shape as illustrated in FIG. 16D. Further, the reflow process of FIG. 16D may be omitted.

The terminal 20A in which the solder 22 is formed to cover the barrier metal 21b formed on the pillar electrode 21a and the pillar electrode 21a of the opening portion 21d formed on the barrier metal 21b, is formed according to the processes of FIG. 7A to FIG. 7C and FIG. 15A to FIG. 16D.

It may not be necessary that the diameter of the opening portion 21d of the barrier metal 21b is controlled at high precision. When the opening portion 21d which reaches the pillar electrode 21a is formed, the diffusion of tin (Sn) to the side surface of the pillar electrode 21a and the breakage of the bonding portion during bonding may be suppressed. Further, when the opening portion 21d which reaches the pillar electrode 21a is formed, since copper (Cu) is supplied from the pillar electrode 21a during forming the compound 23, all tin (Sn) of the solder 22 may be changed into the compound 23.

Further, the terminal 20B as described above may be made to have a circular shape or a substantially circular shape when viewed from a top surface. In addition, the terminal 20B may be made to have an elliptical shape or a substantially elliptical shape, a quadrangular shape or a substantially quadrangular shape or a triangular shape or a substantially triangular shape when viewed from a top surface.

Further, though the opening portion 21d is formed on the central portion of the barrier metal 21b in the terminal 20B as described above, the opening portion 21d may not be formed on the central portion of the barrier metal 21b. Even when the opening portion 21d is formed at an outer side than the central portion of the barrier metal 21b, the effect of the preferential diffusion of tin (Sn) of the solder 22 to the pillar electrode 21a of the opening portion 21d and the volume contraction of the bonding portion during bonding, may be obtained. Accordingly, the diffusion of tin (Sn) to the side surface of, for example, the pillar electrode 21a and breakage of the bonding portion may be suppressed.

Further, the terminal 20B as described above includes the pillar electrode 21a made of copper (Cu). Here, the pillar electrode 21a made of copper (Cu) include the pillar electrode 21a having copper (Cu) as major components in addition to the pillar electrode 21a made of pure copper (Cu). The barrier metal 21b made of nickel (Ni) includes the barrier metal 21b having nickel (Ni) as major components in addition to the barrier metal 21b made of pure nickel (Ni).

Further, a combination of materials used in the pillar electrode 21a and the barrier metal 21b is not limited to a combination of copper (Cu) (e.g., including materials of which major component is copper) and nickel (Ni) (e.g., including materials of which major component is nickel (Ni)) as described above. A component of materials to be used in the solder 22 is needed to have a diffusion coefficient which is larger for the pillar electrode 21a and smaller for the barrier metal 21b.

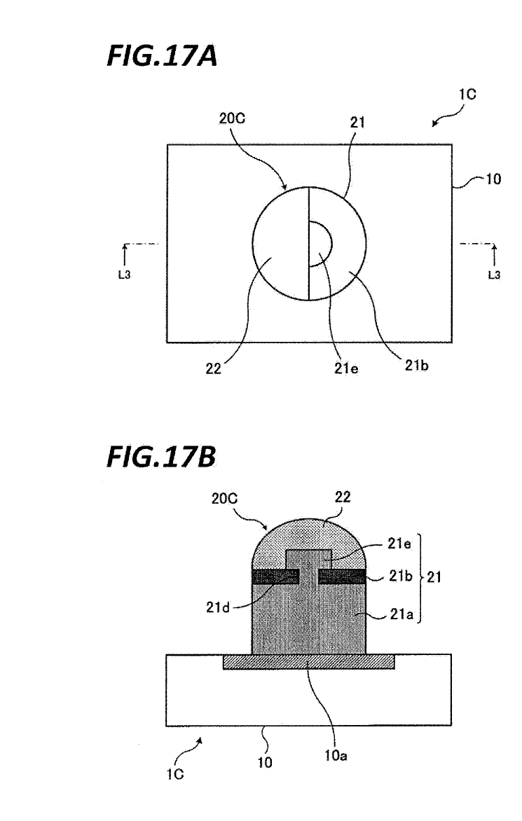

A third embodiment will be described next. FIG. 17 is a view illustrating an exemplary terminal according to the third embodiment. FIG. 17A is a plan view illustrating principal portions of an example of the electronic component provided with the terminal according to the third embodiment. FIG. 17B is a cross sectional view illustrating principal portions of an example of the electronic component provided with the terminal according to the third embodiment. FIG. 17B is a cross sectional view taken along line L3-L3 of FIG. 17A. A portion of solder is not illustrated in FIG. 17A for convenience.

An electronic component 1C illustrated in FIG. 17A and FIG. 17B is provided with a terminal 20C protruded from the wiring portion 10a provided on the main body portion 10. Further, here, a single terminal 20C is illustrated for convenience, but a plurality of terminals 20C may be provided on the main body portion 10.

The terminal 20C includes the electrode portion 21 and the solder 22 (e.g., a solder portion) formed on the electrode portion 21. The electrode portion 21 includes the pillar electrode 21a (e.g., a conductive portion) provided on the wiring portion 10a and the barrier metal 21b (e.g., a conductive portion) provided on the pillar electrode 21a. The opening portion 21d which reaches the pillar electrode 21a below the barrier metal 21b is formed on the barrier metal 21b. The opening portion 21d is formed on the central portion of the barrier metal 21b in this example. The protrusion 21e which is provided on the pillar electrode 21a of the opening portion 21d and protruded from the barrier metal 21b by penetrating the barrier metal 21b is formed on the electrode portion 21 of the terminal 20C. A material which reacts with a predetermined component contained in the solder 22 to form a compound is used in the protrusion 21e. The solder 22 is formed to cover the barrier metal 21b and the protrusion 21e.

A material having Tin (Sn) as main component is used in the solder 22. A material, such as for example, copper (Cu) is used in the pillar electrode 21a of the electrode portion 21. A component contained in the solder 22, that is, a material having a different diffusion coefficient with respect to tin (Sn) is used in the barrier metal 21b and the protrusion 21e of the electrode portion 21 in this example. Here, a material having a diffusion coefficient with respect to tin (Sn) which is lower than that of the protrusion 21e is used in the barrier metal 21b. For example, nickel (Ni) is used in the barrier metal 21b and for example, copper (Cu) is used in the protrusion 21e. Herein-below, the terminal 20C using materials exemplified as above will be described by way of an example.

As described above, in the terminal 20C, an opening portion 21d is formed in the barrier metal 21b made of nickel (Ni) and the protrusion 21e protruded from the protrusion 21e made of copper (Cu) by penetrating the barrier metal 21b to reach the pillar electrode 21a made of copper (Cu) below the barrier metal 21b is formed. As described above, the barrier metal 21b and the protrusion 21e made of copper (Cu) having a higher diffusion coefficient with respect to tin (Sn) are exposed on the top surface the electrode portion 21 and the barrier metal 21b and the protrusion 21e are covered with the solder 22. Accordingly, tin (Sn) of the solder 22 is preferentially diffused to and reacted with the protrusion 21e of the barrier metal 21b, and further the protrusion 21e of the opening portion 21d or the pillar electrode 21a below the barrier metal 21b when the electronic component 1C and other electronic component are bonded. Accordingly, the diffusion of tin (Sn) to the side surface of the pillar electrode 21a may be suppressed.

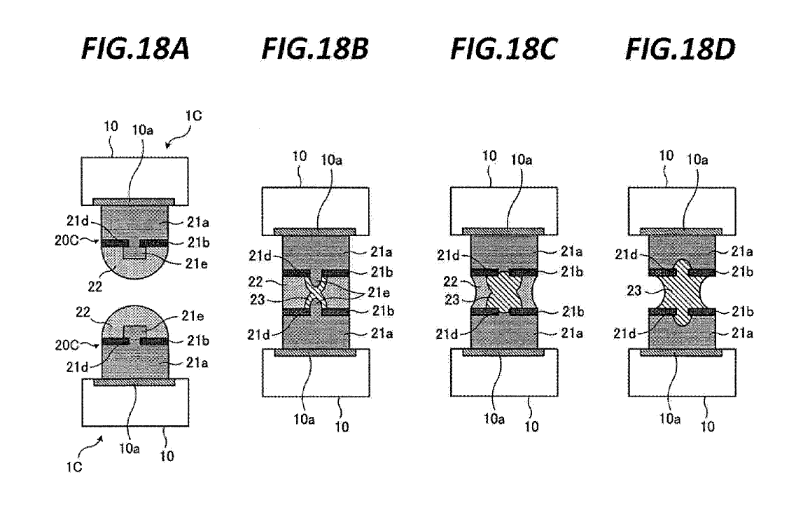

FIG. 18 is a view illustrating an example of bonding between terminals according to the third embodiment. Here, a bonding of the electronic components 1C provided with the terminal 20C as illustrated in FIG. 17 will be described by way an example. FIG. 18A to FIG. 18D illustrate principal portions of an example of the electronic components 1C during bonding.

The terminals 20C are provided on the corresponding positions of the electronic component 1C to be connected in advance. When the terminals 20C are bonded with each other, first, the terminal 20C are disposed to face with each other in the electronic components 1C provided with the terminal 20C as illustrated in FIG. 18A.

Subsequently, the pillar electrodes 21a, on which the barrier metal 21b and the protrusion 21e are formed, of the electronic components 1C are bonded with each other in such a manner that the solder 22 is interposed between the pillar electrodes 21a by pressing the electronic components 1C while heating at a temperature of a melting point or more of the solder 22 as illustrated in FIG. 18B. In this case, tin (Sn) contained in the solder 22 is preferentially diffused to and reacted with the protrusion 21c made of copper (Cu) having a higher diffusion coefficient among the barrier metal 21b made of nickel (Ni) and the protrusion 21e made of copper (Cu) that is protruded from the barrier metal 21b and contacted with the solder 22 to form a compound 23. As reaction of tin (Sn) of the solder 22 with copper (Cu) of the protrusion 21e is progressed, the compound 23 is continued to grow as illustrated in FIG. 18C. Growing of compound 23 may also progress to the protrusion 21e within the opening portion 21d and the pillar electrode 21a in the vicinity of the opening portion 21d.

When the compound 23 is growing, crystals are densely arranged as the compound grows and thus, the volume contraction of the bonding portion between the pillar electrodes 21a (e.g., between the barrier metals 21b) occurs as illustrated in FIG. 18C. The opening portion 21e is formed on the central portion of the barrier metal 21b and the volume contraction of the bonding portion between the pillar electrodes 21a is progressed toward the central portion of the barrier metal 21b as the compound 23 is grown, as illustrated in FIG. 13C and further FIG. 13D.

As described above, the protrusion 21e made of copper (Cu) which reaches the pillar electrodes 21a made of copper (Cu) is formed on the central portion of the barrier metal 21b made of nickel (Ni) and thus, tin (Sn) of the solder 22 is preferentially diffused to and reacted with the protrusion 21e or the pillar electrodes 21a connected to the protrusion 21e to form the compound 23. Further, when the compound 23 is formed, a volume contraction occurs in the bonding portion between the pillar electrodes 21a. Accordingly, the diffusion of tin (Sn) of the solder 22 along the side surface of the barrier metal 21b to the side surface of the pillar electrode 21a may be suppressed by stopping the diffusion flow of the solder 22 at a portion between the opposing pillar electrodes 21a. Further, excessive reaction of the solder 22 and the pillar electrode 21a is suppressed by the barrier metal 21b. As a result, the solder 22 in the bonding portion between the opposing pillar electrodes 21a is reduced and thus, the generation of the broken portion may be suppressed.

In the terminal 20C in which the protrusion 21e reaching the pillar electrode 21a is formed on the central portion of the barrier metal 21b, the size of the protrusion 21e may be adjusted to contain an amount of copper (Cu) which is enough for all tin (Sn) of the solder 22 is changed into the compound 23. Further, in the terminal 20C, even after all copper (Cu) of the protrusion 21e is consumed in forming the compound 23 with tin (Sn) of the solder 22, an amount of copper (Cu) enough for changing all tin (Sn) of the solder 22 into the compound 23 may be supplied from the pillar electrode 21a. According to the terminal 20C, the pillar electrodes 21a may be bonded with the bonding portion in which all tin (Sn) of the solder 22 is changed into the compound 23. Accordingly, the problems such as the generation of pore or the breakage portion caused by the diffusion of the remaining solder 22 may also be suppressed in a heating environment after bonding.

The terminal 20C is provided on the electronic components 1C as described above to implement an electronic apparatus in which the electronic components 1C are connected with high reliability. Further, in the electronic apparatus, all of the solder 22 may not necessarily be changed into the compound to form a bonding state as illustrated in FIG. 18D and may be changed into the compound to form the bonding states as illustrated in FIG. 18B and FIG. 18C. In the electronic apparatus having the bonding states as illustrated in FIG. 18B and FIG. 18C, when being heated later, the diffusion of tin (Sn) to the side surface of the pillar electrode 21a and the breakage of the bonding portion may be suppressed due to the preferential diffusion of tin (Sn) to the protrusion 21e and the volume contraction during forming the compound 23.

While a bonding between the electronic components 1C provided with the terminals 20C is described by way of an example, the effects as described above may be obtained when the electronic component 1C provided with the terminal 20C and other electronic component provided with a terminal having a structure different from the terminal 20C are bonded.

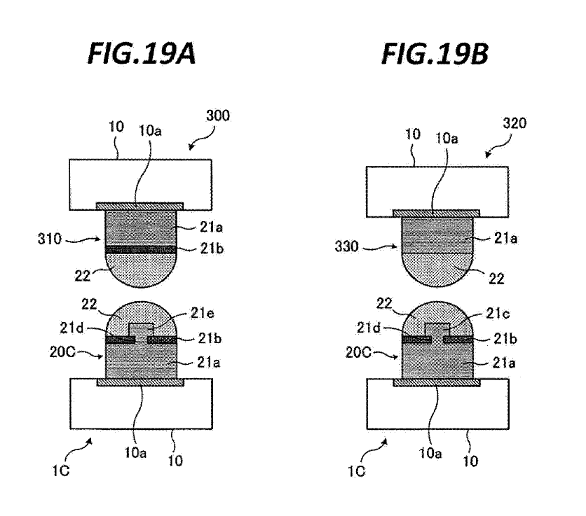

FIG. 19 is an explanatory view of another example of bonding between the terminals according to the third embodiment. In an example of FIG. 19A, the electronic components 1C is bonded with an electronic components 300 which is different from the electronic components 1C. The electronic components 300 is provided with the terminal 310 which includes the pillar electrode 21a and the barrier metal 21b (e.g., which does not include the protrusion 21d). A preferential diffusion of tin (Sn) of the solder 22 to the protrusion 21e and further to the pillar electrode 21a connected to the protrusion 21e and a volume contraction according to formation of the compound 23 are also generated in bonding between the terminal 20C of the electronic component 1C and the terminal 310 of the electronic component 300, similarly to the above-description. Accordingly, the diffusion of tin (Sn) to the side surface of the pillar electrode 21a and the breakage of the bonding portion between the pillar electrodes 21a may be suppressed.

In an example of FIG. 19B, the electronic component 1C is bonded with an electronic component 320 which is different from the electronic component 1C. The electronic component 320 is provided with the terminal 330 (e.g., the pillar electrode, the barrier metal and the wiring portion). The diffusion of tin (Sn) of the solder 22 to the protrusion 21e and further to the pillar electrode 21a connected to the protrusion 21e and the volume contraction according to formation of the compound 23 are also generated in bonding between the terminal 20C of the electronic components 1C and the terminal 330 of the electronic components 320. Accordingly, the diffusion of tin (Sn) to the side surface of the pillar electrode 21a or the terminal 330 and the breakage of the bonding portion between the pillar electrodes 21a may be suppressed.

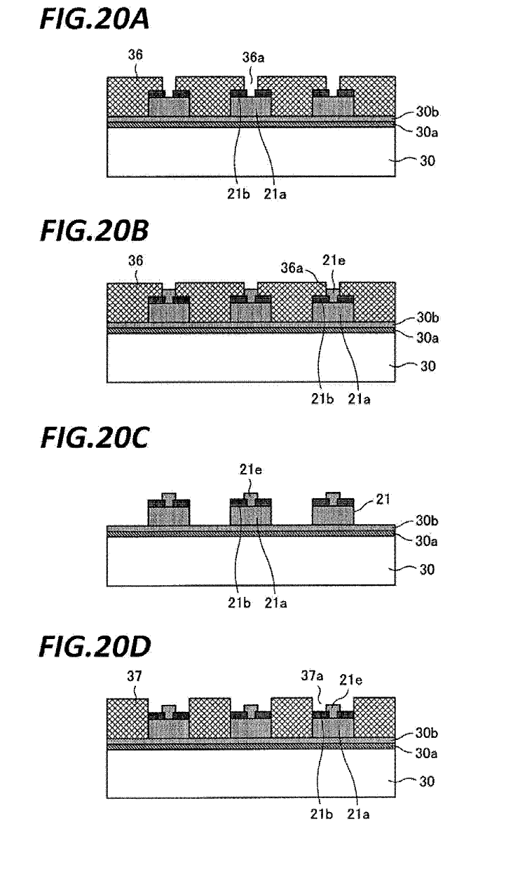

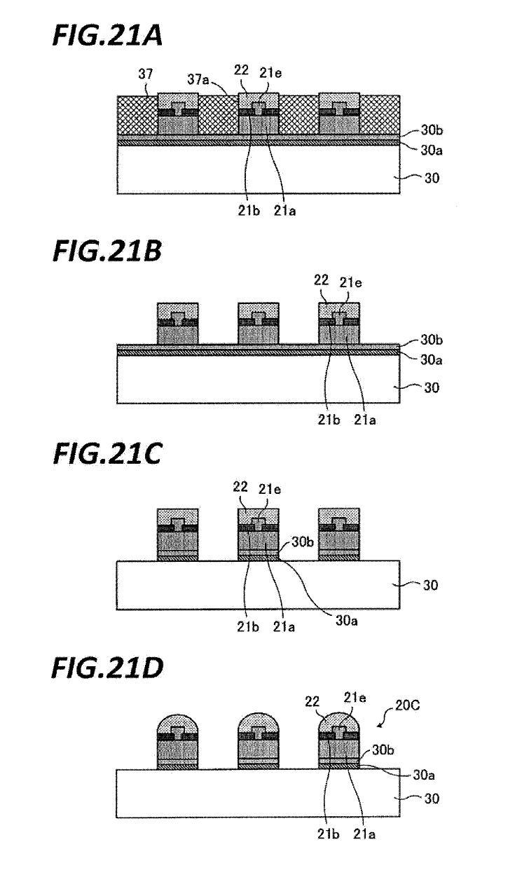

The terminal 20C as described above is provided on the electronic component 1C to implement an electronic apparatus in which the electronic components 1C and other electronic components is connected with high reliability. The method of forming the terminal 20C according to the third embodiment will be described next. Further, the processes of FIG. 7A to FIG. 7C and FIG. 15A to FIG. 15D described in the second embodiment may be the same in forming the terminal 20C according to the third embodiment. Here, processes after the process of FIG. 15D will be described with reference to FIG. 20 and FIG. 21.

FIG. 20 to FIG. 21 are explanatory views of an example of a terminal forming method according to the third embodiment. The cross sectional views of principal portions in each process of a terminal forming method are diagrammatically illustrated in FIG. 20 and FIG. 21. First, after performing the processes of FIG. 7A to FIG. 7C and FIG. 15A to FIG. 15D, resist material is coated, and an exposing process and a developing process are performed on the resist material to form a resist 36 having an opening portion 36a on a location of the opening portion 21d of the barrier metal 21b as illustrated in FIG. 20A. FIG. 20A illustrates a case where the resist 36 having the opening portion 36a of which diameter is larger than that of the opening portion 21d of the barrier metal 21b is formed as an example.

Subsequently, the protrusion 21e is formed on the pillar electrode 21a within the opening portion 21d of the barrier metal 21b as illustrated in FIG. 20B using an electrolytic plating method. For example, a copper (Cu) layer having a height (thickness) of 2 μm from the opening portion 21d as the protrusion 21e is formed.

The resist 36 is peeled off after forming the protrusion 21e as illustrated in FIG. 20C. Accordingly, the barrier metal 21b having the opening portion 21d formed on the central portion is formed on the pillar electrode 21a and the protrusion 21e connected to the pillar electrode 21a is formed on the opening portion 21d to form the electrode portion 21.

Subsequently, as illustrated in FIG. 20D, resist material is coated, and an exposing process and a developing process are performed on the material of resist to form a resist 37 having an opening portion 37a of the electrode portion 21. Subsequently, a solder 22 is formed on the protrusion 21e and the barrier metal 21b within the opening portion 37a of the resist 37 as illustrated in FIG. 21A using an electrolytic plating method. For example, a tin-silver (Sn—Ag) solder having a thickness of 3.5 μm is formed as the solder 22.

After forming the solder 22, the resist 37 is peeled off as illustrated in FIG. 21B, and the seed layer 30b and the adhesion layer 30a exposed after the resist 37 is peeled off are removed by etching as illustrated in FIG. 21C. Then, a reflow process is performed to form the solder 22 having a rounded shape as illustrated in FIG. 21D. Further, the reflow process of FIG. 21D may be omitted.

According to the processes of FIG. 7A to FIG. 7C, FIG. 15A to FIG. 15D and FIG. 20A to FIG. 20D as described above, the terminal 20C is formed in which the solder 22 is formed to cover the barrier metal 21b formed on the pillar electrode 21a and the protrusion 21e which reaches the pillar electrode 21a by penetrating the barrier metal 21b.

The diameter of the opening portion 36a of the resist 36 which is formed in the process of FIG. 20A may be made larger than as well as smaller than that of the opening portion 21d of the barrier metal 21b. Even in a case where the opening portion 36a having the diameter to form the protrusion 21e on the opening portion 36a, when the protrusion 21e is connected to the pillar electrode 21a through the opening portion 21d of the barrier metal 21b, the diffusion of tin (Sn) to the side surface of the pillar electrode 21a and the breakage of the bonding portion during bonding may be suppressed. Further, copper (Cu) is supplied from the pillar electrode 21a during forming of the compound 23 and thus, all tin (Sn) of the solder 22 may be changed into the compound 23.

Further, the terminal 20C as described above may be made to have a circular shape or a substantially circular shape when viewed from a top surface. In addition, the terminal 20C may be made to have an elliptical shape or a substantially elliptical shape, a quadrangular shape or a substantially quadrangular shape or a triangular shape or a substantially triangular shape when viewed from a top surface.

Further, though the opening portion 21d and the protrusion 21e are formed on the central portion of the barrier metal 21b in the terminal 20C as described above, the opening portion 21d and the protrusion 21e may not be formed on the central portion of the barrier metal 21b. Even when the opening portion 21d and the protrusion 21e are formed at an outer side than the central portion of the barrier metal 21b, the effects of the preferential diffusion of tin (Sn) of the solder 22 to the protrusion 21e and the pillar electrode 21a below the protrusion 21e, and the volume contraction of the bonding portion toward the protrusion 21e during bonding, may be obtained. Accordingly, the diffusion of tin (Sn) to, for example, the side surface of the pillar electrode 21a and the breakage of the bonding portion may be suppressed.

Further, the terminal 20C as described above include the pillar electrode 21a made of copper (Cu), the barrier metal 21b made of nickel (Ni), the protrusion 21e made of copper (Cu) as elements. Here, the pillar electrode 21a made of copper (Cu) and the protrusion 21e made of copper (Cu) include the pillar electrode 21a and the protrusion 21e having copper (Cu) as a major component in addition to the pillar electrode 21a made of pure copper (Cu) and the protrusion 21e made of pure copper (Cu). The barrier metal 21b made of nickel (Ni) include the barrier metal 21b having nickel (Ni) as a major component in addition to the barrier metal 21b made of pure nickel (Ni).

Further, a combination of materials used in the pillar electrode 21a, the protrusion 21e and the barrier metal 21b is not limited to a combination of copper (Cu) (e.g., including materials having copper (Cu) as a major component) and nickel (Ni) (e.g., including materials having nickel (Ni) as a major component) as described above. A component of materials to be used in the solder 22 is just needed to have a diffusion coefficient which is larger for the pillar electrode 21a and the protrusion 21e, and smaller for the barrier metal 21b.

A compound may be formed between the electrode portion 21 and the solder 22 in the reflow processes of FIG. 9D, FIG. 16D, FIG. 21D when forming the terminals 20A, 20B, 20C according to the first to third embodiments as described above.

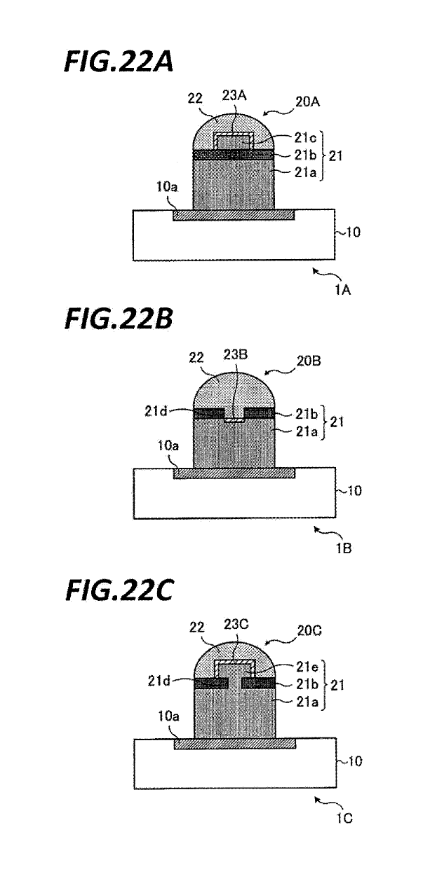

FIG. 22 is a view illustrating another example of a reflow process. The cross sectional views of principal portions of other examples of the terminals 20A, 20B, 20C of the reflow process are diagrammatically illustrated in FIG. 22A, FIG. 22B, FIG. 22C, respectively.

In the reflow process of FIG. 9D, for example, as illustrated in FIG. 22A, a compound (e.g., copper-tin (Cu—Sn) compound) 23A may be formed on the surface of the protrusion 21c. Further, a compound (e.g., nickel-tin (Ni—Sn) compound) may be formed on the surface of the barrier metal 21b along with the compound 23A.

In the reflow process of FIG. 16D, for example, as illustrated in FIG. 228, a compound (e.g., copper-tin (Cu—Sn) compound) 23B may be formed on the surface of the pillar electrode 21a of the opening portion 21d formed on the barrier metal 21b. Further, a compound (e.g., nickel-tin (Ni—Sn) compound) may be formed on the surface of the barrier metal 21b along with the compound 23B.

In the reflow process of FIG. 21D, for example, as illustrated in FIG. 22C, a compound (e.g., copper-tin (Cu—Sn) compound) 23C may be formed on the surface of the protrusion 21e. Further, a compound (e.g., nickel-tin (Ni—Sn) compound) may be formed on the surface of the barrier metal 21b along with the compound 23C.

A compound may also be formed between the electrode portion 21 and solder 22, similar to a case for the terminal 20A, in the reflow processes of FIG. 10D and FIG. 11D when the terminals 20Aa, 20Ab are formed.

A fourth embodiment will be described next. Here, a bonded member (e.g., an electronic apparatus) in which the electronic component provided with the terminal described in the first embodiment and other electronic component are bonded, and an evaluation result for the bonded member will be described.

For evaluation, a semiconductor chip having a chip size of 13 mm×10 mm and a terminal of which diameter is 10 μm and terminal pitch is 50 μm is used as an electronic component. A terminal in which a nickel (Ni) layer having a height of 7 μm is formed, a copper (Cu) layer having a thickness of 3 μm is formed on the central portion of the nickel (Ni) layer and a solder layer made of tin-silver (Sn—Ag) having a thickness of 5 μm is formed on the copper (Cu) layer is used. The terminal described above is used as the terminal of a lower semiconductor chip of the bonded member. A terminal in which a copper (Cu) layer having a height of 10 μm is formed and a solder layer made of tin-silver (Sn—Ag) having a thickness of 5 μm is formed on the copper (Cu) layer is used as the terminal of an upper semiconductor chip of the bonded member. It is assumed that a bonded member in which the terminals of the upper and lower semiconductor chips as described above are bonded to each other is referred to as an embodiment.

Further, for comparison, a semiconductor chip provided with a terminal in which a copper (Cu) layer having a height of 7 μm is formed, a nickel (Ni) layer having a thickness of 3 μm is formed on the copper (CU) layer and further, a solder layer made of tin-silver (Sn—Ag) having a thickness of 5 μm is formed on the nickel (Ni) layer is used as a lower semiconductor chip of the bonded member. A semiconductor chip provided with a terminal in which a copper (Cu) layer having a height of 10 μm is formed and a solder layer made of tin-silver (Sn—Ag) having a thickness of 5 μm is formed on the copper (Cu) layer is used as an upper semiconductor chip of the bonded member. It is assumed that a bonded member in which the terminals of the upper and lower semiconductor chips as described above are bonded to each other is referred to as a comparative example.

Any of the comparative example and the embodiment is manufactured according to a flow to be described below. That is, a flux is coated on the terminal at least one of the upper and lower semiconductor chips and then, the upper and lower semiconductor chips are made to be opposed by being aligned with each other using a flip chip bonder. Then, the upper and lower semiconductor chips are heated at a head temperature of 300° C. for, for example, ten seconds to melt the solder layer, thereby bonding the terminals of the upper and lower semiconductor chips with each other. A cross-sectioning is performed with respect to the bonded member manufactured as described above, and an element analysis is performed for a cross-section using EPMA (Electron Probe Micro Analyzer) for an evaluation.

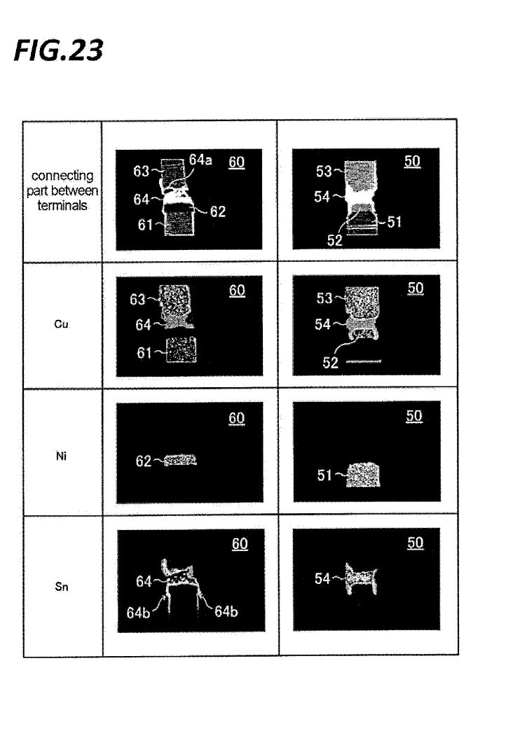

FIG. 23 is a view illustrating an example of a result of evaluation. Further, an example of the element analysis using the EPMA is diagrammatically illustrated in FIG. 23. FIG. 23 illustrates the element analyses for the bonding portion 50 between the terminals of the bonded member of the embodiment manufactured as described above, the bonding portion 60 between the terminals of the bonded member of the comparative example, and each element of copper (Cu), nickel (Ni) and tin (Sn) of the bonding portions 50, 60 between the terminals.

The bonding portion 50 between the terminals of the embodiment includes a nickel (Ni) layer 51 formed at a lower portion, a copper (Cu) layer 52 partially formed on the nickel (Ni) layer 51, a copper (Cu) layer 53 formed at an upper portion and a bonding layer 54 containing the solder component. The bonding portion 60 between the terminals of the comparative example includes a copper (Cu) layer 61 formed at a lower portion, a nickel (Ni) layer 62 partially formed on the copper layer 61, a copper (Cu) layer 63 formed at an upper portion and a bonding layer 64 containing the solder component. Pores (e.g., pored portion 64a) are formed in the bonding layer 64 in the bonding portion 60 between the terminals of the comparative example while the bonding layer 54 in the bonding portion 50 between the terminals of the embodiment has a substantially dense structure.

The bonding layer 64 containing copper (Cu) is formed between the nickel (Ni) layer 62 on the lower (Cu) layer 61 and the upper copper (Cu) layer 63 in the bonding portion 60 between the terminals of the comparative example from the analysis result of copper (Cu) and nickel (Ni) of FIG. 23. The bonding layer 64 contains Tin (Sn), and Tin (Sn) is diffused to the side surface of the lower nickel (Ni) layer 62 or to the side surface of the copper (Cu) layer 6 under the lower nickel (Ni) layer 62 (diffusion portion 64b) from the analysis result of tin (Sn) of FIG. 23.

The bonding layer 54 containing copper (Cu) is formed between the lower nickel (Ni) layer 51 and the copper (Cu) layer 52 and the upper copper (Cu) layer 53 in the bonding portion 50 between the terminals of the embodiment from the analysis result of copper (Cu) and nickel (Ni) of FIG. 23. The bonding layer 54 contains Tin (Sn) from the analysis result of tin (Sn) of FIG. 23. The diffusion of tin (Sn) to the side surface of the nickel (Ni) layer 51 which is seen in the bonding portion 60 between the terminals of the comparative example has not been formed in the bonding portion 50 between the terminals of the embodiment. In bonding portion 50 between the terminals of the embodiment, it may be said that the diffusion of tin (Sn) to the side surface of the nickel (Ni) layer 51 is suppressed due to an effect of diffusion of tin (Sn) to the copper (Cu) layer 52 on the nickel (Ni) layer 51 and the volume contraction toward the copper layer 52.

As described above, a terminal which includes an electrode portion and a solder portion on the electrode portion is used as the terminal of the electronic component such as the semiconductor chip. In the terminal, the conductive portions having diffusion coefficients with respect to a component of the solder portion are formed on the top surface of the electrode portion, and the solder portion is formed to cover the conductive portions. The terminal described above is used such that when the electronic components are bonded with each other, the component of the solder portion is preferentially diffused to the conductive portion having a higher diffusion coefficient for the component and the effect of volume contraction of a compound caused by the preferential diffusion of the component of the solder portion occurs, thereby suppressing the diffusion of the component of the solder portion to the side surface of the electrode portion. Accordingly, the generation of breakage in the bonding portion where the electronic components are bonded with each other may be suppressed and thus, an electronic apparatus in which the electronic components are bonded to each other with high reliability may be implemented.

A structure is exemplified in the above description in which two kinds of the conductive portions (e.g., copper (Cu) and nickel (Ni)) having different diffusion coefficients with respect to the component of the solder 22 are formed on the top surface of the electrode portion 21, and the solder 22 is formed on the conductive portions. In addition, when a terminal is configured to have a structure in which three or more kinds of conductive portions are formed on the top surface of the electrode portion 21, at least two of these conductive portions are made as the conductive portions having different diffusion coefficients with respect to the component of the solder 22, and the solder 22 is formed on the conductive portions, the same effect as that described above may be obtained.

Further, a bonding between the electronic components such as the semiconductor chip is exemplified in the above description. However, the structure of the terminal described above may be applied to a case where the electronic component and a component other than the electronic component are bonded to each other and also to a case where the components other than the electronic component are bonded to each other. For example, when the components are bonded using solder, a metal layer of copper (Cu) and a barrier layer of nickel (Ni) formed on the metal layer are formed on a surface on which both components are to be bonded. Also, a protrusion of copper (Cu) on the barrier layer, an opening portion in the barrier layer or a protrusion of copper (Cu) formed in an opening portion of the barrier layer is formed on at least one of the electronic components according to the example of the terminal of the electronic components. The components described above are bonded with each other using solder and thus, a reduction of solder in the bonding portion between the components and a breakage of the bonding portion are suppressed. Accordingly, the components may be bonded with each other with a high seal-ability.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic component comprising:
an electrode portion; and
a solder portion formed on the electrode portion,
wherein the electrode portion includes a first conductive portion and a second conductive portion each having different diffusion coefficient with respect to a component of the solder portion on a top surface of the electrode portion, and
the solder portion is formed on the first conductive portion and the second conductive portion.

2. The electronic component according to claim 1, wherein the first conductive portion is provided at an outer side of the second conductive portion and a diffusion coefficient with respect to the component of the solder portion of the first conductive portion is smaller than that of the second conductive portion.

3. The electronic component according to claim 2, wherein the second conductive portion is a conductive portion partially formed on the first conductive portion.

4. The electronic component according to claim 2, wherein the first conductive portion includes a through hole formed on the second conductive portion to reach the second conductive portion.

5. The electronic component according to claim 2, wherein the electrode portion includes a third conductive portion having a diffusion coefficient with respect to the component of the solder portion which is larger than that of the first conductive portion,
the first conductive portion includes a through hole which is formed on the third conductive portion to reach the third conductive portion, and
the second conductive portion is formed on the through hole.

6. A manufacturing method of an electronic component, comprising:
preparing a first electronic component which includes a first electrode portion and a solder portion formed on the first electrode portion and in which the first electrode portion includes a first conductive portion and a second conductive portion, each having a different diffusion coefficient with respect to a component of the solder portion, on a top surface of the first electrode portion, and the solder portion is formed on the first conductive portion and the second conductive portion;
preparing a second electronic component provided with a second electrode portion; and
bonding the first electrode portion and the second electrode portion in such a manner that the first electronic component is made to oppose to the second electronic component and the first and second electronic components are heated at a temperature of a melting point or more of the solder portion.

7. The manufacturing method according to claim 6, wherein the first conductive portion is provided at an outer side of the second conductive portion and a diffusion coefficient with respect to the component of the solder portion of the first conductive portion is smaller than that of the second conductive portion.

8. The manufacturing method according to claim 7, wherein the bonding of the first electrode portion and the second electrode portion includes forming a compound which contains a component of the solder portion and a component of the second conductive portion.

9. The manufacturing method according to claim 7, wherein the second conductive portion is partially formed on the first conductive portion.

10. The manufacturing method according to claim 7, wherein the first conductive portion includes a through hole formed on the second conductive portion to reach the second conductive portion.

11. The manufacturing method according to claim 7, wherein the first electrode portion includes a third conductive portion having a diffusion coefficient with respect to the component of the solder portion which is larger than that of the first conductive portion,
the first conductive portion includes a through hole which is formed on the third conductive portion to reach the third conductive portion, and
the second conductive portion is formed on the through hole.

12. An electronic apparatus comprising:
a first electronic component provided with a first electrode portion;
a second electronic component provided with a second electrode portion disposed to be opposed to the first electrode portion; and
a bonding portion that bonds the first electrode portion and the second electrode portion,
wherein the bonding portion contains a solder component,
the first electrode portion is provided with a first conductive portion and a second conductive portion, each having different diffusion coefficient with respect to a component of the solder portion, on a top surface of the first electrode portion, and
the solder portion is formed on the first conductive portion and the second conductive portion.

13. The electronic apparatus according to claim 12, wherein the first conductive portion is provided at an outer side of the second conductive portion and a diffusion coefficient to the component of the solder portion of the first conductive portion is smaller than that of the second conductive portion.

14. The electronic apparatus according to claim 13, wherein the bonding portion includes a compound which contains the solder component and a component identical to the component of the second conductive portion.

15. The electronic apparatus according to claim 13, wherein the second conductive portion is partially formed on the first conductive portion.

16. The electronic apparatus according to claim 13, wherein the first conductive portion includes a through hole which is formed on the second conductive portion to reach the second conductive portion.

17. The electronic apparatus according to claim 13, wherein the electrode portion includes a third conductive portion having a diffusion coefficient with respect to the component of the solder portion which is larger than that of the first conductive portion,
the first conductive portion includes a through hole which is formed on the third conductive portion to reach the third conductive portion, and
the second conductive portion is formed on the through hole.
